(19) United States
(12) Patent Application Publication
(10) Pub. No.: US 2024/0304424 A1
(43) Pub. Date: Sep. 12, 2024

(54) CERAMIC FIBERS FOR SHIELDING IN VACUUM CHAMBER SYSTEMS AND METHODS FOR USING SAME

(71) Applicant: Helion Energy, Inc., Everett, WA (US)

(72) Inventors: Brian Campbell, Shoreline, WA (US); David Kirtley, Seattle, WA (US); Anthony Pancotti, Kenmore, WA (US); Christopher James Pihl, Woodinville, WA (US); George Votroubek, Monroe, WA (US)

(73) Assignee: Helion Energy, Inc., Everett, WA (US)

(21) Appl. No.: 18/654,572

(22) Filed: May 3, 2024

Related U.S. Application Data
(63) Continuation of application No. PCT/US2022/079394, filed on Nov. 7, 2022.
(60) Provisional application No. 63/276,300, filed on Nov. 5, 2021.

(51) Int. Cl. H01J 37/32; C01B 33/18; D01F 9/08; D07B 1/02; F16J 15/08; F16J 15/10

(52) U.S. Cl. CPC H01J 37/32495; C01B 33/18; D01F 9/08; D07B 1/02; F16J 15/0806; F16J 15/102; H01J 37/32513; H01J 37/3266; H01J 37/32862; D07B 2201/2009; D07B 2205/301; D07B 2501/20; D10B 2505/06

(57) ABSTRACT

A method and apparatus to shield various components (e.g., a gasket, a sensor, a wire, a mechanical component made of metals and/or polymers) deployed in a vacuum environment using a shield assembly formed from multiple ceramic fibers. The shield assembly reduces damage to the components when exposed to a plasma and the generation of contaminants. The ceramic fibers are formed from a ceramic and arranged in a packed structure creating a tortuous trajectory that suppresses the transport of charged particles and/or contaminants through the shield assembly. The ceramic fibers are mechanically compliant and readily bent and/or packed into gaps without fracture. The ceramic fibers may also be formed into a tube to surround a fiberglass rod, a gasket, a sensor, and/or a wire. The presence of the shield assemblies also permits cleaning of the interior surfaces of the vacuum chamber using a plasma without generating contaminants from the gaskets.

### CROSS-REFERENCE TO RELATED PATENT APPLICATION(S)

This application is a bypass continuation of International Application No. PCT/US2022/079394, filed on Nov. 7, 2022, which claims priority to U.S. Provisional Application No. 63/276,300, filed on Nov. 5, 2021, entitled “CERAMIC FIBERS FOR SHIELDING IN VACUUM CHAMBER SYSTEMS AND METHODS FOR USING SAME.” Each of these applications is incorporated herein by reference in its entirety.

### BACKGROUND

A vacuum chamber system creates a low pressure (i.e., vacuum) environment, which may be used to store, process, and/or otherwise handle various substances and/or devices for a variety of applications. For example, vacuum chamber systems are often used in semiconductor foundries to facilitate the deposition of materials (e.g., chemical vapor deposition, sputtering) and the removal of materials (e.g., reactive ion etching, plasma cleaning). In another example, vacuum chamber systems are used to provide a controlled environment for experimentation (e.g., simulating outer space conditions to test materials and devices) or to facilitate the operation of a device or system (e.g., a transmission electron microscope). In yet another example, vacuum chamber systems are used to accelerate or translate charged particles using magnetic fields and/or electric fields (e.g., particle accelerators).

A conventional vacuum chamber system typically includes a vacuum chamber assembled from multiple parts or portions, such as chamber walls, chamber endplates, and/or the like. For every pair of parts that are connected together (e.g., at their edges, at their respective surfaces, combinations thereof), a seal is generally disposed between the connecting components of the respective parts to seal any gaps that would otherwise form due to imperfections of the connecting surfaces/edges (e.g., surface roughness, misalignment of surfaces). The seal may generally limit or, in some instances, inhibit transport of a fluid (a gas, a liquid), plasma constituents, and/or the like between the connecting surfaces/edges. For example, the seal may be a gasket, which typically includes a mechanically compliant material, such as a soft metal (e.g., copper, aluminum) or an elastomer (e.g., Buna-N, silicone, fluorocarbon, perfluorocarbon), that deforms and fills the imperfections of the mating surfaces when the parts are clamped together, thus forming the seal.

The seal also protects the various parts or portions of the vacuum chamber. For example, vacuum chambers formed of materials that are hard and brittle (e.g., ceramics) are prone to fracture, particularly at the points of connection between adjacent parts. A compliant seal material helps dampen any relative movement and softens any impact between the different portions of the vacuum chamber. For ceramic vacuum chambers, in particular, elastomeric gaskets are generally used to seal the vacuum due to the higher mechanical compliance of elastomers compared to metals. The compliant material is typically formed as a closed loop (e.g., a ring). The compliant material is also often supported by a rigid holder (e.g., a metallic ring) for alignment and positioning.

### SUMMARY

The Inventors have recognized and appreciated that vacuum chamber systems may provide a controlled environment to contain and manipulate various substances. However, the Inventors have also recognized seals made from metals and elastomers are often a source of contaminants into the vacuum environment, which may react with the substance in an undesirable manner.

For example, a vacuum chamber may contain a plasma undergoing one or more reactions (e.g., a chemical or a nuclear reaction) and the introduction of contaminants may interfere with the reactions (e.g., by leading to different, unwanted chemical reactions, or by sapping energy from the plasma thus preventing nuclear reactions from occurring). In another example, the vacuum chamber system may be a particle accelerator, such as those used for fundamental research or generation of industrial or medical isotopes, and the introduction of contaminants from stray particles impacting gaskets or sensors inside the vacuum chamber may take energy away from the intended charged particles, or change the trajectories of charged particles contained therein in an undesirable manner. In yet another example, the vacuum chamber system may be configured to deposit and/or grow materials on a substrate and the presence of contaminants may reduce the quality of the material. For instance, the presence of contaminants may decrease the purity of the deposited film or create unwanted crystal morphologies. In applications where higher vacuum environments are desirable, such as the production of ever smaller-scale semiconductors or higher-temperature plasmas, the generation of contaminants from the gaskets and/or the leakage from the gaskets due to degradation may also limit the vacuum level attainable.

As an illustrative example, FIGS. 1A and 1B show a conventional vacuum chamber system 10 containing a plasma 40 controlled by magnetic fields. As shown, the vacuum chamber system 10 includes a vacuum chamber 11, which provides a desirable environment to control the composition and geometry of the plasma. The vacuum chamber 11 is assembled from chamber walls 12a and chamber endplates 14a-1 and 14a-2 (also sometimes generally referred to herein as a “chamber endplate 14a”) mounted to opposing ends of the chamber walls 12a. The chamber walls 12a and the chamber endplates 14a-1 and 14a-2 together define a cavity 13. The vacuum chamber 11 further includes a pair of gasket assemblies 20a-1 and 20a-2 with gaskets 22 to seal gaps formed between the chamber walls 12a and the chamber endplates 14a-1 and 14a-2. As shown in FIG. 1B, the gasket 22 is disposed within a gap 16a formed between the chamber walls 12a and the chamber endplate 14a-2. The gasket 22 is generally a flexible component that forms a closed loop spanning the periphery of the mating surfaces.

The vacuum chamber system 10 further includes a pump 36 mounted to the chamber endplate 14a-2 to evacuate the cavity 13 and a plasma source 38 mounted to the chamber endplate 14a-2 to transfer the plasma 40 into the cavity 13. The vacuum chamber system 10 further includes a magnetic field source 34 with multiple coils disposed around the chamber walls 12a to generate a magnetic field that can confine and shape the plasma 40. Alternatively, electric fields may also be used to control and modify the shape and size of the plasma 40 in the vacuum chamber system 10.

The plasma 40 contains highly energized, charged particles (e.g., ions, electrons) that may be ejected towards the interior surfaces of the vacuum chamber 11. When a charged particle strikes the interior surfaces of the vacuum chamber 11, contaminants may be sputtered off the interior surfaces of the vacuum chamber 11 and enter the plasma 40.

The generation of contaminants may be controlled to some extent by forming the chamber walls 12a and the chamber endplates 14a-1 and 14a-2 from materials that are more resistant to vaporization when exposed to charged particles ejected from the plasma 40. In applications where the chemical or nuclear reactions supported by the plasma 40 are sensitive to the presence of specific contaminants, the materials forming the chamber walls 12a and the chamber endplates 14a-1 and 14a-2 are also often chosen such that, in the event contaminants are generated, the composition of the contaminants do not react with the plasma 40 in an undesirable manner.

For example, in some applications, the plasma 40 primarily contains hydrogen and helium ions. Under these conditions, it is often preferable for the chamber walls 12a and the chamber endplates 14a-1 and 14a-2 to be formed from a material that does not contain heavy elements, such as tungsten, that may otherwise take away thermal energy from the plasma. If a magnetic field generated externally from the vacuum chamber 11 is used to modify the shape of the plasma 40, the chamber walls 12a and the chamber endplates 14a-1 and 14a-2 are also typically formed of a dielectric so that the vacuum chamber 11 does not behave as an electrical conductor that affects the transmission and/or spatial distribution of the magnetic fields in the chamber 11. One example of material that meets these conditions is silicon dioxide (SiO₂), which can generate less contaminants compared to, for example, metals and elastomers.

For ceramic vacuum chambers, however, elastomeric gaskets are generally used to seal the vacuum chamber 11 as discussed above. The elastomers are typically hydrocarbon-based materials, which, when the charged particles of the plasma strike the gasket, may generate large amounts of carbon and fluorine impurities, which are contaminants that react with the ions of the plasma 40 in an undesirable manner. For example, FIG. 1A shows the magnetic field source 34 may generate a magnetic field with magnetic field lines that directly intersects the gasket assemblies 20a-1 and 20a-2. For clarity, FIG. 1A only shows a single representative magnetic field line 42, but it should be appreciated that magnetic fields penetrate all of the vacuum chamber volume during normal operation (with multiple representative magnetic field lines present). A charged particle 44 ejected from the plasma 40 near the magnetic field line 42 typically travels along the magnetic field line 42 with a spiral trajectory. As shown in FIG. 1B, the combination of the magnetic field line 42 intersecting the gasket 22 and the flat geometry of the gap 16a results in the charged particle 44 having a direct trajectory 45a to strike the gasket 22 and produce a contaminant 46. The contaminant 46, in turn, typically becomes ionized and charged within the plasma and thus itself follows a direct trajectory 47a along the magnetic field line 42 towards the plasma 40. The Inventors have recognized that vacuum chamber systems designed to contain a plasma have employed various approaches to reduce the generation of contaminants from elastomeric gaskets often at the expense of a compromised or less reliable seal, higher manufacturing costs, and increased complexity.

One common approach is to reduce the flow conductance of the contaminants between the source of the contaminants (e.g., a plasma) and the gasket. This may be accomplished, for example, by shaping and dimensioning the parts and portions of the vacuum chamber to increase the distance the contaminants travel before striking the gasket. In other words, the gaskets are positioned far from the plasma. In another example, the gasket assemblies may form tortuous trajectories (also sometimes generally referred to as tortuous pathways) between the gasket and the source of the contaminants (e.g., the charged particles ejected from a plasma). Said in another way, the gasket assemblies may force the contaminants to follow a non-linear, circuitous path with multiple obstacles, such as the vacuum chamber walls, that may capture the contaminants via collisions between the contaminants and the obstacles.

In one example, FIG. 2A shows a cross-sectional view of another gasket assembly 20b disposed between a chamber wall 12b and a chamber endplate 14b. Here, the chamber wall 12b includes a lip 24 and the chamber endplate 14b includes a lip 26, which together form a step-lap joint. As shown, the lips 24 and 26 form a gap 16b with a step profile and the gasket 22-1 is disposed in an interior portion of the gap 16b. The step profile creates a tortuous trajectory between the cavity 13 of the vacuum chamber 11 and the gasket 22-1 for charged particles and contaminants to follow, reducing the likelihood of a charged particle ejected from the plasma 40 striking the gasket 22-1 and a contaminant generated from the gasket 22-1 traveling back to the plasma 40.

Specifically, FIG. 2A shows the magnetic field 42 does not provide a direct trajectory for the charged particle 44 to strike the gasket 22-1. Instead, the charged particle 44 may follow a trajectory 45b in which the charged particle 44 only strikes the gasket 22-1 after reflecting off the surfaces of the chamber wall 12b and the chamber endplate 14b multiple times. Each time the charged particle 44 strikes the chamber wall 12b or the chamber endplate 14b, the energy of the charged particle 44 may be absorbed by the chamber wall 12b or the chamber endplate 14b, thus the charged particle 44 may not even strike the gasket 22-1. For example, the charged particle 44 may sputter the chamber wall 12b or the chamber endplate 14b instead of the gasket 22-1. Similarly, if a charged particle 44 manages to produce a contaminant 46, the contaminant 46 may also strike the surfaces of the chamber wall 12b and the chamber endplate 14b multiple times before entering the cavity 13 as indicated by the trajectory 47b. Each time the contaminant 46 strikes the chamber wall 12b or the chamber endplate 14b, the contaminant 46 may be deposited onto the chamber wall 12b or the chamber endplate 14b.

Although the gasket assembly 20b reduces the presence of contaminants from the elastomeric gaskets in the plasma 40, the complex geometry of the chamber wall 12b and the chamber endplate 14b typically makes forming a seal more challenging and harder to maintain and/or replace. As shown in FIG. 2A, the gasket assembly 20b often includes a second gasket 22-2 to further seal the gap 16b. Additionally, the chamber wall 12 typically includes a port 28 coupled to another pump (not shown) to facilitate the removal of any gases in the intermediate space 18 between the gaskets 22-1 and 22-2 when the vacuum chamber system 10 is pumped down to vacuum further increasing the complexity of the vacuum chamber system 10. The more complex geometry associated with these gasket assemblies creates additional design challenges and increases the complexity and cost of manufacture and assembly. For example, the parts or portions of the vacuum chamber may thermally expand and collide due to the more complex geometry. In another example, the vacuum chamber components may be more difficult to fabricate and the assembly of the vacuum chamber is more sensitive to misalignment between the parts.

In another example, ring inserts may be inserted into the vacuum chamber to generate tortuous trajectories. FIG. 2B shows a gasket assembly 20c disposed between the chamber walls 12a and the chamber endplate 14a. As before in the gasket assembly 20a, the gasket assembly 20c includes a gasket 22 disposed in the gap 16a formed between the chamber walls 12a and the chamber endplate 14a. However, for this approach, the gasket assembly 20c further includes a ceramic ring 30 disposed in the cavity 13 of the vacuum chamber 11 proximate to or abutting the interior surfaces of the chamber wall 12 and the chamber endplate 14a near the gap 16a. The ceramic ring 30 is typically formed from a ceramic material, such as SiO₂, that produces less reactive contaminants with the plasma 40.

As shown in FIG. 2B, the outer surface 32 of the ceramic ring 30 and the interior surfaces of the chamber wall 12a and chamber endplate 14a forms a narrow channel. This arrangement creates tortuous trajectories 45c and 47c for the charged particles 44 and the contaminants 46, respectively, thus reducing the generation of contaminants 46 and subsequent presence of contaminants 46 in the plasma 40. Compared to the gasket assembly 20b, the geometry of the gasket assembly 20c is relatively simpler. However, the ceramic ring 30 is typically quite fragile and prone to fracture, for example, during manufacture, during installation of the ceramic ring 30 into the vacuum chamber 11, or due to changes in environmental conditions (e.g., ambient temperature). Thus, the utility of the ceramic ring 30 is limited particularly for larger-sized vacuum chambers 11 (e.g., vacuum chambers with a nominal width greater than 1 m). The ceramic ring may not work for non-symmetric geometries as well. It may also protrude into the vacuum chamber, impinging on the plasma and disrupting its shape or direction of travel.

The Inventors have further recognized the generation of contaminants in vacuum chamber systems designed to contain a plasma is not limited to the gaskets. More generally, contaminants may be generated from any components installed in the vacuum chamber system, especially components composed of metallic and/or polymeric materials. This includes sensors to monitor various operating parameters of the vacuum chamber system and/or the properties of the substance contained therein, electrical wiring, and various mechanical components (e.g., a frame to support the sensors). Additionally, the components may partially lose or cease to function due to degradation over time due to the continuous bombardment of charged particles. Although the added functionality provided by these components can be desirable, these components are typically not included in vacuum chamber systems designed to contain a plasma or, more generally, a highly energetic substance due to the bombardment issues described above.

The Inventors have also recognized the challenges associated with the generation of contaminants in previous vacuum chamber systems are also encountered for mechanical systems that operate in a natural vacuum environment, such as space. For example, a plasma propulsion system may generate a plasma in space to move a spacecraft. The plasma propulsion system may be constructed in a similar manner to the vacuum chamber system 10. In particular, the plasma propulsion system includes a plasma propulsion chamber, which is typically assembled from multiple walls or segments to separate an internal compartment of the spacecraft from the surrounding vacuum environment. Similar to the vacuum chamber system 10, the plasma propulsion chamber often includes multiple gaskets to seal gaps in the plasma propulsion chamber. The plasma propulsion system also often includes sensors or other equipment disposed in the propulsion chamber cavity or near the exhaust that may be damaged when exposed to the plasma.

It should be appreciated the generation of contaminants is not limited to vacuum chamber systems that contain a plasma. More generally, vacuum chamber systems may include a variety of substances, components, and/or devices that generate contaminants in various applications as described above. For example, the plasma source 38 in the vacuum chamber system 10 of FIGS. 1A and 1B may be replaced with a specimen source that provides a desired substance to the cavity 13, such as a gas, charged particles, a plasma, or a substrate to facilitate the deposition or etching of materials.

In view of the foregoing limitations of previous vacuum chamber systems, the present disclosure is directed to various inventive implementations of vacuum chamber systems and plasma propulsion systems that include one or more shield assemblies that are each formed, at least in part, from multiple ceramic fibers and inventive methods of using shield assemblies with ceramic fibers to shield various components and/or materials disposed in a vacuum environment. The present disclosure is also directed to various inventive methods for installing the shield assemblies into the vacuum chamber system and methods for using a vacuum chamber system with one or more shield assemblies. The vacuum chamber systems described herein generally include a vacuum chamber assembled from two or more parts, such as a chamber wall and a chamber endplate, that form one or more gaps with gasket assemblies to seal gaps formed between the parts, and a pump coupled to the vacuum chamber to evacuate a cavity defined by the vacuum chamber. Although the vacuum chamber systems disclosed herein include gasket assemblies with one or more gaskets, it should be appreciated these are non-limiting examples. More generally, the vacuum chamber systems may include other types of seals, such as a silicone-based sealant.

In some implementations, the vacuum chamber system may further include a specimen source to transfer a desired substance into the vacuum chamber. For example, the specimen source may be a plasma source to generate and inject a plasma into the cavity of the vacuum chamber. The plasma source may include a gas source that provides ionizable gas and electrodes to ionize the gas. The vacuum chamber system may also include a magnetic field source that generates a magnetic field to confine and shape the plasma. For example, the magnetic field source may include an array of magnetic coils connected to a current source. Although the vacuum chamber systems described herein include a plasma source, it should be appreciated these are non-limiting examples and that the shield assemblies described herein may generally be used to inhibit the transport of undesirable contaminants within a vacuum chamber in many different manufacturing, research, and other applications (e.g., vacuum chamber systems for material deposition, material etching, a particle accelerator for research or isotope generation, a transmission electron microscope, a scanning electron microscope).

It should be appreciated that, in some implementations, magnetic fields are not the only mechanism to control the shape and/or size of the plasma. For example, an electric field (static or time varying) generated by an electric field source may also be used to control the shape and/or size of the plasma. It should also be appreciated that, in some implementations, vacuum chamber systems described herein that contain a plasma may have no control over the shape and/or size of the plasma.

In one aspect, the ceramic fibers of the shield assembly reduce the exposure of various components in the vacuum chamber to charged particles ejected from the plasma and, in turn, reduce the generation of undesirable contaminants within the vacuum chamber. These components include, but is not limited to a gasket, a sensor, an electrical wire, a metallic and/or polymeric component, or a mechanical component to support any of the foregoing. This may be accomplished, in part, by forming the ceramic fibers from a material that resists sputtering or degradation when impacted by charged particles or plasma, including those particles at a many keV temperature, produces fewer contaminants that are less likely to enter the plasma or particle stream and disrupt the chemical or nuclear performance of the substance (e.g., fewer carbon and fluorine contaminants), and/or is stable at room temperature and higher temperatures (e.g., 20° C. to 300° C.). It should be appreciated that the temperature range at which the material is stable is a non-limiting example and that the ceramic fibers may be formed from a material that is stable at lower or higher temperatures. Additionally, the ceramic fibers may intrinsically have many small interstitial spaces and complex structures. For example, the fibers may be wound or braided in a manner conceptually similar to textiles, such as yarns formed from organic fibers. This arrangement forms tortuous trajectories within the fiber or arrangement of fibers that inhibit the transport of charged particles from the plasma through the ceramic fibers and to the component to be protected (e.g., the gasket or sensor) and the transport of contaminants to the plasma.

The shield assembly may be generally placed between the plasma and the component to be shielded. For example, the shield assembly may be placed between the plasma and a gasket (e.g., an elastomeric gasket). The shield assembly may be disposed between, or partially over, for example, a chamber wall and a chamber endplate, a pair of chamber walls, a window and a baseplate of a chamber wall or a chamber endplate, and/or the like. Such elastomeric gaskets may be used to seal any gaps formed between the parts of the vacuum chamber while the shield assembly reduces or, in some instances, effectively prevents charged particles from interacting with the gasket. In another example, the shield assembly may wrap around a component to protect the component from the plasma. The component includes, but is not limited to, a gasket, a mechanical component (e.g., an elastically deformable component such as a metal, polymer, or fiberglass rod, a bolt head), one or more electrical wires, a camera, or a sensor (e.g., a magnetic field or flux sensor, a plasma density sensor, a temperature sensor, a Langmuir probe, sensors to detect neutrons, alpha particles, and/or electrons) to measure some aspect of the plasma and/or an operating condition of the vacuum chamber system, such as the energy of the plasma, plasma density, plasma temperature, or the vacuum pressure.

In another aspect, the ceramic fibers may be appreciably more flexible and durable compared to ceramic rings (e.g., the ceramic ring 30). This may be accomplished, in part, by using ceramic fibers that are shaped and dimensioned to have an appreciably smaller bending stiffness compared to the ceramic rings. This may be achieved, in part, by the ceramic fibers having a relatively smaller cross-sectional width and a relatively longer length. Although the ceramic fibers may be formed from materials that are mechanically brittle in bulk form, the low bending stiffness of the ceramic fibers allows the ceramic fibers to be bent at appreciably large angles without imparting large mechanical stresses on the ceramic fiber. For example, the ceramic fibers may have a diameter that ranges between about 0.1 μm and about 100 μm, including all values and sub-ranges in between. More generally, the shield assemblies may be formed from ceramic fibers that have different sizes and/or spacings so long as a tortuous trajectory is formed to inhibit the transport of various particulates (e.g., charged particles, contaminants). The ceramic fibers may have a length that ranges between, for example, about 0.1 m to about 100 m, including all values and sub-ranges in between. It should be appreciated the dimensions of the ceramic fibers disclosed herein are non-limiting examples and that, more generally, ceramic fibers of different dimensions may also be used to form a shield assembly.

The mechanical compliance of the ceramic fibers may allow the shield assembly to be readily placed against various surfaces of the vacuum chamber with different geometries without fracture and/or shaped into various geometries to facilitate installation and protection of various components. The geometries include, but are not limited to, a rope, a tube, and a flat sheet. For example, the shield assembly may be readily packed into the gaps of the vacuum chamber sealed by the gaskets and subsequently compressed during assembly of the vacuum chamber. Friction and compression alone may be sufficient to hold the shield assembly in place. In another example, the shield assembly may be used as a flexible sheath where the ceramic fibers are shaped into a tube to surround, for example, a sensor, one or more electrical wires, and/or a mechanical component (e.g., a fiberglass rod). In some implementations, the rod may be elastically deformed when placed into the vacuum chamber to generate an internal restoring force that maintains the shield assembly in a desired location. For instance, the shield assembly may be placed in a gap to shield a gasket and the internal restoring force may be directed outwards away from the cavity to retain the shield assembly in the gap. In this example, the shield assembly may also be used to shield a sensor or a wire in the vacuum chamber. In yet another example, the shield assembly may be used as a tape where the ceramic fibers are shaped into a film and one side of the film is coated with an adhesive. In this manner, the ceramic tape may be applied to the interior surfaces of the vacuum chamber to cover various components. In some implementations, the ceramic fibers may be wound together to maintain the shape of the film. In some implementations, the adhesive may hold the ceramic fibers in place while the ceramic fibers protect the adhesive from, for example, charged particles ejected by the plasma.

In yet another aspect, the presence of the shield assemblies in the vacuum chamber system may permit the interior surfaces of the vacuum chamber to be more easily cleaned without generating additional contaminants. Another challenge with vacuum chamber systems is that the contaminants in the ambient environment, such as water molecules, may become adsorbed onto the interior surfaces of the vacuum chamber during assembly and/or maintenance of the vacuum chamber system. For example, water molecules may infiltrate the cavity when the vacuum chamber is open and exposed to the ambient environment. During operation, the plasma may also eject charged particles and/or reaction products, which may be adsorbed by the wall as contaminants. When the vacuum chamber is subsequently pumped down to vacuum, the adsorbed contaminants may take substantially longer to remove due to the surface adhesion forces binding the contaminants to the surfaces of the vacuum chamber, thus increasing the time to reach a desired vacuum level. For example, it may take a few seconds to empty a vacuum chamber of contaminants that are not adhered to the wall, but hours or days to remove those contaminants that are adhered.

To accelerate the removal of the adsorbed contaminants, a plasma may be injected into the vacuum chamber to substantially fill the cavity of the vacuum chamber for the purposes of locally heating the interior surfaces of the vacuum chamber. The plasma may be a lower energy plasma or a plasma supporting chemical or nuclear reactions. When the temperature of the interior surfaces increases, the rate at which the adsorbed contaminants are removed from the surfaces and purged increases. The challenge with this approach has historically been that it also causes sputtering and release of particles from the unprotected gaskets. The presence of the shield assemblies may reduce the exposure of the elastomeric gaskets to the cleaning plasma and, hence, reduce or, in some instances, effectively prevent the generation of contaminants during the cleaning process.

In some implementations, the chamber walls and/or the chamber endplates may also be formed from a ceramic material, such as SiO₂. Thus, the interior surfaces of the vacuum chamber exposed to the plasma may be substantially or, in some instances, all ceramic. In some implementations, the plasma may be at a lower energy to facilitate removal of the contaminants without sputtering off material from the vacuum chamber. For comparison, the plasma during normal operation of the vacuum chamber system may be at a higher energy to facilitate desired reactions and confined to a smaller volume via the magnetic field generated by the magnetic field source.

The ceramic fibers may generally be formed from nonporous ceramic materials that do not outgas at vapor pressures ranging from, for example, about 10⁻³ Torr to about 10⁻⁸ Torr, including all values and sub-ranges in between. It should be appreciated the vapor pressures are non-limiting examples and that, more generally, nonporous ceramic materials may be chosen that do not outgas at other vapor pressures depending on the operating environment within the vacuum chamber system. Various ceramic materials may be used to form the ceramic fibers including, but not limited to, silicon dioxide (SiO₂), aluminum oxide (Al₂O₃), boron nitride (BN), boron carbide (BC), silicon nitride (SiN), aluminum nitride (AlN), and any combinations of the foregoing (e.g., 50% SiO₂:50% BN). In some implementations, the ceramic fibers may be formed from the same material as the chamber walls and/or the chamber endplates so that the contaminants sputtered off the shield assembly are the same as the contaminants sputtered off the chamber walls and/or the chamber endplates.

In some implementations, the ceramic fibers may be formed from high purity ceramic materials to reduce the generation of contaminants when the ceramic fibers are exposed to, for example, charged particles ejected by a plasma. For example, ceramic fibers formed from SiO₂ may have a SiO₂ mass fraction greater than or equal to about 0.98. In some implementations, the SiO₂ mass fraction may be greater than or equal to about 0.9995. In another example, the ceramic fibers may be formed from 50:50 mixtures of SiO₂ and BN where the mass fractions of SiO₂ and BN are between about 0.4 and 0.60, including all values and sub-ranges in between. In some implementations, the mass fractions of SiO₂ and BN may each be about 0.5. In some implementations, the mass fraction of the impurities in the ceramic material used to form the ceramic fibers may be less than or equal to 0.05. It should be appreciated the mass fractions of the constituent materials described above are non-limiting examples. For some applications, the ceramic fibers may be formed of lower purity ceramic materials. For example, in a plasma composed of higher-atomic mass elements, the plasma may be more tolerant to contaminants originating from the ceramic fibers. In another example, in a hydrogen plasma, lower purity ceramic materials may still be used particularly if the impurities are lower atomic mass elements, such as silicon, boron, nitrogen, or oxygen. Moreover, lower purity ceramic materials may be used provided the generation of contaminants does not appreciably degrade the shield assembly over time.

It should also be appreciated a number of mixtures are possible and may vary based on, for example, the desired material properties. For example, the ceramic fibers may be formed from any mixture of two or more materials. In another example, the mixture may be tailored so that the ceramic fibers have a similar composition to the chamber walls and endplates, or material properties (e.g., dielectric properties) similar to the chamber walls and endplates or other materials that do not interact with the plasma in an undesirable manner.

In some implementations, the composition and mass fraction of the constituent materials may also vary based on the impact of any contaminants that may be generated from the ceramic fibers. For example, in a hydrogen plasma, the presence of higher atomic mass contaminants, such as tungsten, may absorb or radiate away energy from the plasma. Thus, it may be preferable for the ceramic fibers to be formed of lower atomic mass elements, such as silicon, boron, nitrogen, or oxygen, so that the contaminants generated are lower atomic mass contaminants, which are less disruptive to the hydrogen plasma. In another example, in a plasma composed of higher-atomic mass elements, such as in the production of novel isotopes, the plasma may be less sensitive to the presence of higher atomic mass contaminants. Thus, the ceramic fibers may be formed of low and/or high atomic mass elements.

Additionally, the density of the ceramic fibers may generally depend on the density of the ceramic material and the volume fraction of the fibers relative to the volume fraction of the interstitial space between the fibers. In one example, a shield assembly formed from ceramic fibers made of SiO₂ may have a density of about 1060 kg/m³. which is lower than the density of bulk SiO₂ (˜2410 kg/m³) due to the presence of interstitial spaces between the fibers.

It should be appreciated that the density of the shield assembly may vary based on the ceramic material used to form the fibers. It should also be appreciated the density of the shield assembly may change during preparation and installation (e.g., when the plastic coating or greases are removed, when the fibers are packed into a gap in the vacuum chamber). In some implementations, the density of the shield assembly may be as low as 10% of the density of the bulk ceramic. It should be appreciated the density of the shield assembly is non-limiting and that, more generally, any density may be used provided the shield assembly forms tortuous trajectories that cause the particles to exhaust its energy before passing through the shield assembly.

It should also be appreciated the shield assemblies described herein are not limited to being formed only from ceramic fibers. Rather, ceramic materials in other geometric configurations may be used as well. For example, the shield assemblies may be formed, in part, from perforated ceramic films that also have many small interstitial spaces and complex structures to create tortuous trajectories. In another example, the shield assemblies may be formed from ceramic wool where the ceramic fibers arranged in an amorphous manner similar to cotton. In yet another example, the shield assemblies may be formed from ceramic felt where the ceramic fibers are pressed together to form a mat.

In some implementations, the ceramic fibers may be a commercial off-the-shelf product, such as Saint-Gobain Quartzel® fiber. Typical commercial ceramic fibers are generally not suitable for use in a vacuum environment due, in part, to the presence of a plastic coating or a grease. Before the shield assembly is installed in the vacuum chamber, the ceramic fibers are cleaned to remove any undesirable organic materials on the ceramic fibers. For example, the ceramic fibers may be placed into an oven (e.g., a kiln) and heated to a sufficiently high temperature to burn off organic materials without melting or altering the structure of the ceramic fibers. In implementations where the ceramic fibers are formed from SiO₂, the ceramic fibers may be heated to a temperature of about 1200° C. for 24 hours and subsequently cooled to room temperature. It should be appreciated the foregoing temperature and duration constitutes a non-limiting example. Other temperatures and/or durations may be used so long as organic materials are sufficiently removed without melting or altering the structure of the ceramic fibers.

The ceramic fibers may be cut and formed into a desired shape before or after cleaning. In some implementations, the ceramic fibers may be initially wound and/or bundled in the desired shape, such as a tube or a rope, and cut to the desired length before being cleaned in the oven. For example, the ceramic fibers may be wound into a yarn and the yarn may be subsequently wound into a rope.

In installations where the shield assembly forms part of a gasket assembly together with a gasket, the gasket may be first installed in the gap formed between the parts of the vacuum chamber first and partially compressed, for example, by pressing the parts of the vacuum chamber together via a bolt or a clamp. The shield assembly may then be inserted into the gap and the vacuum chamber may be further tightened to fully compress the gasket so that the gasket seals the gap. As the gasket is compressed, the shield assembly may also be squeezed to fill in the gap. In other words, the ceramic fibers are pressed together reducing the amount of interstitial space between the ceramic fibers. Alternatively, the gasket and the shield assembly may be installed onto the vacuum chamber at the same time so that the gasket and the shield assembly are compressed together.

The shield assemblies described herein are not limited to vacuum chamber systems. In some implementations, the shield assemblies may also be integrated into systems that operate in a naturally occurring vacuum environment, such as a spacecraft deployed in outer space. For example, an example plasma propulsion system for a spacecraft may include a plasma propulsion chamber assembled from two or more parts, such as a chamber wall and a chamber endplate, to separate the surrounding vacuum environment from an internal compartment of the spacecraft. One or more gasket assemblies with shield assemblies may be disposed between the gaps of the plasma propulsion chamber. Additionally, one or more sensors, wires, or other devices disposed in the cavity of the plasma propulsion chamber may be surrounded by a shield assembly to reduce the exposure of the foregoing components to the plasma.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A shows a cross-sectional view of a conventional vacuum chamber system with a plasma source and a magnetic field generator.

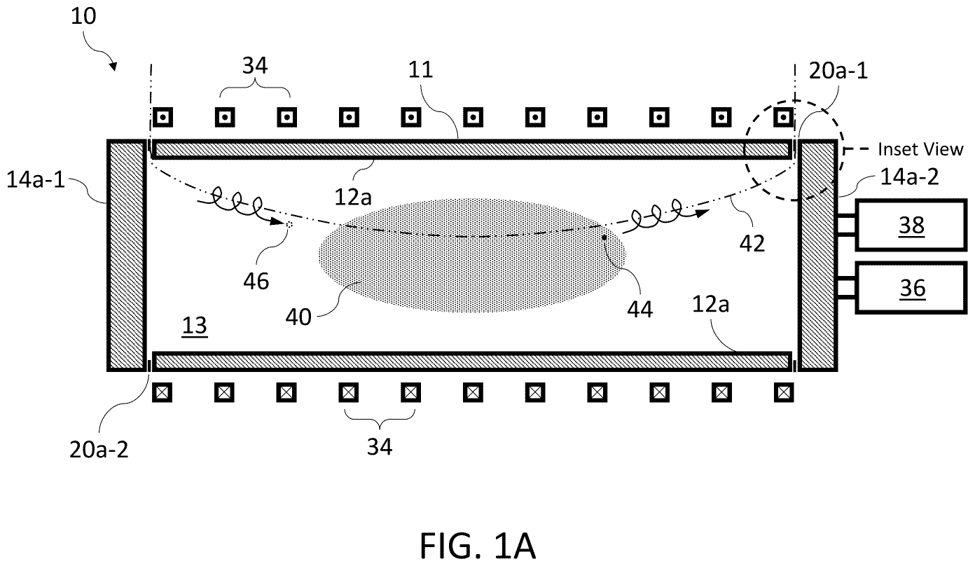

FIG. 1B shows a magnified view of a conventional gasket assembly in the vacuum chamber system of FIG. 1A corresponding to the inset view labeled ‘Inset View.’

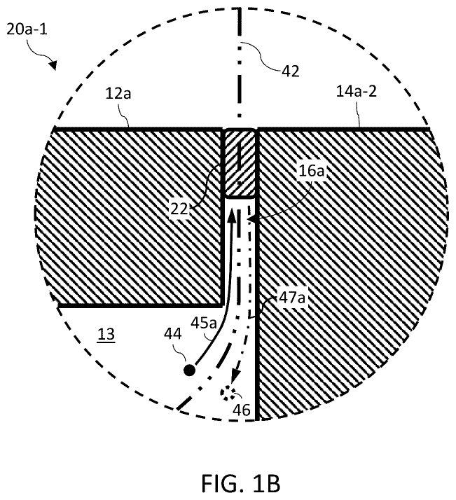

FIG. 2A shows a magnified view of another conventional gasket assembly where the chamber walls and chamber endplates are shaped to form a step-lap joint.

FIG. 2B shows a magnified view of another conventional gasket assembly with a ceramic ring.

FIG. 3A shows a cross-sectional view of an example vacuum chamber system with gasket assemblies that include a ceramic fiber shield assembly, a plasma source, and a magnetic field generator.

FIG. 3B shows a magnified view of the gasket assembly disposed between a chamber wall and a chamber endplate in the vacuum chamber system of FIG. 3A corresponding to the inset view labeled ‘Inset View 1.’

FIG. 3C shows a magnified view of the gasket assembly disposed between a pair of chamber walls in the vacuum chamber system of FIG. 3A corresponding to the inset view labeled ‘Inset View 2.’

FIG. 3D shows a magnified view of the gasket assembly disposed in a chamber endplate supporting a window in the vacuum chamber system of FIG. 3A corresponding to the inset view labeled ‘Inset View 3.’

FIG. 4 shows a magnified view of the ceramic rope in the vacuum chamber system of FIG. 3A.

FIG. 5 shows a cutaway view of one chamber wall in the vacuum chamber system of FIG. 3A and the gasket assembly of FIG. 3C where the end portions of the ceramic rope overlap one another along one side of the gap formed by the chamber wall.

FIG. 6 shows a cutaway view of the chamber endplate supporting the window in the vacuum chamber system of FIG. 3A and the gasket assembly of FIG. 3D where the end portions of the ceramic rope overlap one another along the gap formed between the window and the base plate.

FIG. 7A shows a perspective view of an example ceramic tube.

FIG. 7B shows a cross-sectional view of the ceramic tube corresponding to the plane A-A of FIG. 7A.

FIG. 7C shows a perspective view of the ceramic tube of FIG. 7A surrounding a rod.

FIG. 7D shows a magnified view of an example gasket assembly that includes the ceramic tube and the rod of FIG. 7C disposed between the chamber wall and the chamber endplate in the vacuum chamber system of FIG. 3A.

FIG. 8A shows a top view of an example ceramic tape.

FIG. 8B shows a cross-sectional view of the ceramic tape corresponding to the plane A-A of FIG. 8A.

FIG. 8C shows a perspective view of an interior portion of two chamber walls in the vacuum chamber system of FIG. 3A where the ceramic tape of FIG. 8A is applied on the interior surfaces of the chamber walls to cover a sensor and the gap formed between the chamber walls.

FIG. 9A shows a magnified view of the gasket assembly of FIG. 3C during assembly of the vacuum chamber system. The gasket assembly includes a gasket that is placed in a gap between the chamber walls and partially compressed by pressing the chamber walls together.

FIG. 9B shows a magnified view of the gasket assembly of FIG. 9A where a ceramic rope is inserted into the gap after the gasket is partially compressed.

FIG. 9C shows a magnified view of the gasket assembly of FIG. 9B where the gasket and the ceramic rope are further compressed by pressing the chamber walls together.

FIG. 10A shows a magnified view of the gasket assembly of FIG. 3D during assembly of the vacuum chamber system. The gasket assembly includes a gasket and a ceramic rope that are placed together in a gap between a window and a base plate of the chamber endplate.

FIG. 10B shows a magnified view of the gasket assembly of FIG. 10A where the gasket and the ceramic rope are compressed by pressing the window onto the base plate via a clamp.

FIG. 11 shows a cross-sectional view of the vacuum chamber system of FIG. 3A with a plasma that substantially fills a cavity of the vacuum chamber.

FIG. 12 shows a cross-sectional view of an example plasma propulsion system with gasket assemblies that include a ceramic fiber shield assembly, a plasma source, and a magnetic field generator.

### DETAILED DESCRIPTION

Following below are more detailed descriptions of various concepts related to, and implementations of, a vacuum chamber system and a shield assembly formed, at least in part, from multiple ceramic fibers to reduce, mitigate, or eliminate the transport of charged particles ejected from a plasma and/or contaminants towards the plasma. It should be appreciated that various concepts introduced above and discussed in greater detail below may be implemented in multiple ways. Examples of specific implementations and applications are provided primarily for illustrative purposes so as to enable those skilled in the art to practice the implementations and alternatives apparent to those skilled in the art.

The figures and example implementations described below are not meant to limit the scope of the present implementations to a single embodiment. Other implementations are possible by way of interchange of some or all of the described or illustrated elements. Moreover, where certain elements of the disclosed example implementations may be partially or fully implemented using known components, in some instances only those portions of such known components that are necessary for an understanding of the present implementations are described, and detailed descriptions of other portions of such known components are omitted so as not to obscure the present implementations.

In the discussion below, various examples of inventive vacuum chamber systems and shield assemblies are provided, wherein a given example or set of examples showcases one or more particular features of a vacuum chamber, a gasket assembly, a shield assembly, or a ceramic fiber. It should be appreciated that one or more features discussed in connection with a given example of a vacuum chamber system or a shield assembly may be employed in other examples of vacuum chamber systems and shield assemblies according to the present disclosure, such that the various features disclosed herein may be readily combined in a given vacuum chamber system or a given shield assembly according to the present disclosure (provided that respective features are not mutually inconsistent).

Certain dimensions and features of the vacuum chamber system and/or the shield assembly are described herein using the terms “approximately,” “about,” “substantially,” and/or “similar.” As used herein, the terms “approximately,” “about,” “substantially,” and/or “similar” indicates that each of the described dimensions or features is not a strict boundary or parameter and does not exclude functionally similar variations therefrom. Unless context or the description indicates otherwise, the use of the terms “approximately,” “about,” “substantially,” and/or “similar” in connection with a numerical parameter indicates that the numerical parameter includes variations that, using mathematical and industrial principles accepted in the art (e.g., rounding, measurement or other systematic errors, manufacturing tolerances, etc.), would not vary the least significant digit.

An Example Vacuum Chamber System with Ceramic Fiber Shield Assemblies

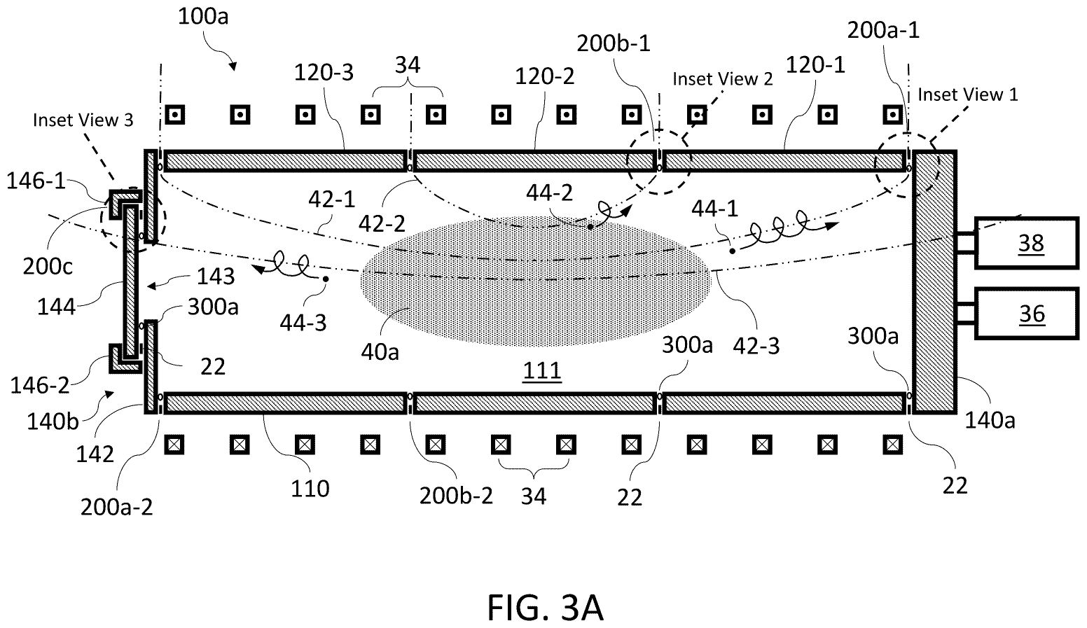

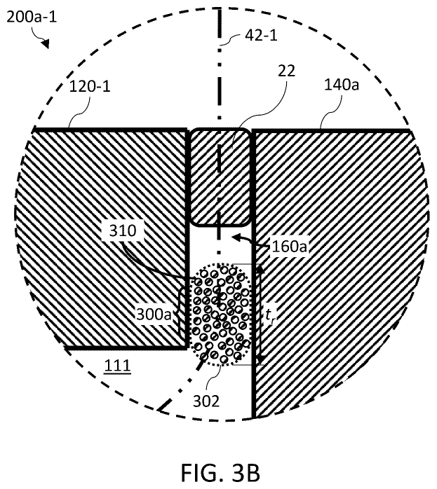

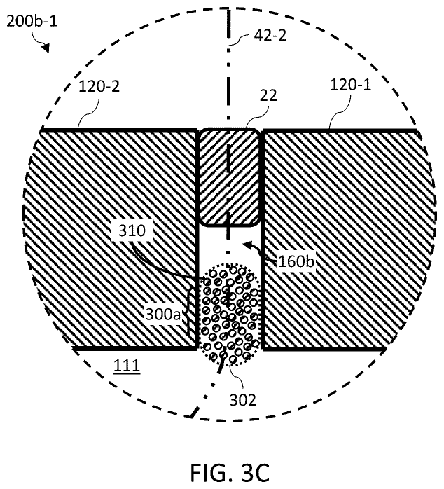

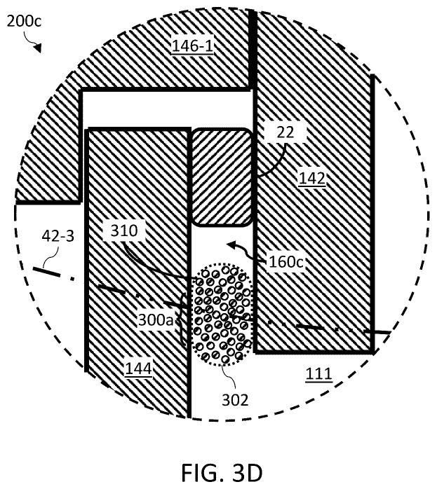

FIG. 3A shows an example vacuum chamber system 100a configured to contain a plasma 40a with one or more shield assemblies 300a formed of multiple ceramic fibers 310 to protect various components of the vacuum chamber system 100a from charged particles (e.g., ions, electrons) ejected from the plasma 40a and reduce the generation of contaminants that, in turn, may adversely affect the plasma 40a. The components protected by the shield assemblies 300a include (but are not limited to) the gasket assemblies 200a-1, 200a-2, 200b-1, 200b-2, and 200c. Further below is a discussion of the various constituent components of the vacuum chamber system 100a.

As shown in FIG. 3A, the vacuum chamber system 100a includes a vacuum chamber 110 that defines a cavity 111 to contain the plasma 40a. The vacuum chamber 110 may be assembled from multiple parts or components, such as multiple chamber walls 120-1, 120-2, and 120-3 (also referred to herein as a “chamber wall 120”) coupled end-to-end, a chamber endplate 140a coupled to the chamber wall 120-1, and a chamber endplate 140b coupled to the chamber wall 120-3. It should be appreciated the combination of components used to form the vacuum chamber 110 is a non-limiting example. More generally, the vacuum chamber 110 may be assembled from any combination of two or more chamber walls, chamber endplates, and/or the like. This, in turn, may result in one or more interfaces and/or one or more gaps where the parts of the vacuum chamber 110 mate to one another.

The chamber walls 120-1, 120-2, and 120-3 may respectively define different portions of the vacuum chamber 110. In some implementations, the chamber walls 120-1, 120-2, and 120-3 may have different geometries (e.g., cylindrical, frustoconical) and/or dimensions. FIG. 3A shows the chamber walls 120-1, 120-2, and 120-3 may be dimensioned such that one chamber wall is directly coupled to another chamber wall. However, it should be appreciated that, in some implementations, the vacuum chamber 110 may include one or more flange adapters to couple together respective pairs of chamber walls. The chamber endplate 140b further includes a window 144 coupled to a base plate 142 via clamps 146-1 and 146-2 (also referred to herein as a “clamp 146”). The base plate 142 defines an aperture 143 and the window 144 covers the aperture 143 to provide a viewing port into the cavity 111 of the vacuum chamber 110. In some implementations, the window 144 may be transparent to light in the visible spectrum. The vacuum chamber 110 may further include one or more ports to provide connection with other components of the vacuum chamber system 100a, such as sensors, wiring, specimen source 38, pump 36. The vacuum chamber 110 may also include windows disposed on any one of the chamber walls 120 or chamber endplates 140a and 140b.

In the vacuum chamber system 100a, the vacuum chamber 110 further includes gasket assemblies disposed at every interface where the parts of the vacuum chamber 110 mate to one another. Specifically, the vacuum chamber 110 includes (i) the gasket assembly 200a-1 with a gasket 22 disposed between the chamber wall 120-1 and the chamber endplate 140a, (ii) the gasket assembly 200a-2 with a gasket 22 disposed between the chamber wall 120-3 and the chamber endplate 140b, (iii) the gasket assembly 200b-1 with a gasket 22 disposed between the chamber walls 120-1 and 120-2, (iv) the gasket assembly 200b-2 with a gasket 22 disposed between the chamber walls 120-2 and 120-3, and (v) the gasket assembly 200c with a gasket 22 disposed between the window 144 and the base plate 142 of the chamber endplate 140b. The gasket assemblies 200a-1 and 200a-2 are also referred to herein as a “gasket assembly 200a” and the gasket assemblies 200b-1 and 200b-2 are also referred to herein as a “gasket assembly 200b.” Each of the gasket assemblies 200a, 200b, and 200c may include a shield assembly 300a to reduce or, in some instances, mitigate the exposure of the gaskets 22 to the plasma 40a and any charged particles (e.g., ions, electrons) ejected from the plasma 40a. It should be appreciated that, in some implementations, the gasket assemblies and particularly the shield assemblies disclosed herein may be disposed at one or a subset of the interfaces formed by the vacuum chamber components (e.g., an interface that is prone to exposure to the charged particles).

The gasket 22 may have a closed-loop geometry, such as a ring or a tube, with various cross-sectional geometries designed to sufficiently fill a gap of the vacuum chamber and form a seal. However, it should be appreciated that, in some implementations, the gasket 22 may include two or more sections of gasket material that collectively form a closed-loop geometry after assembly. In some implementations, the gasket 22 may also have a geometry to aid the alignment and installation of the gasket 22 during assembly of the vacuum chamber system 100a. For example, the gasket 22 may have a L-shaped or T-shaped cross-sectional shape that physically contacts an outer surface of the vacuum chamber 110 to position the gasket 22 at a desired depth into the gap between the various parts or portions forming the vacuum chamber 110.

The chamber endplate 140a includes the pump 36 to evacuate the cavity 111. In some implementations, the pump 36 may evacuate the cavity 111 down to a pressure ranging from about 10⁻³ Torr to about 10⁻⁸ Torr, including all values and sub-ranges in between. It should be appreciated the foregoing vacuum pressures of the cavity 111 are non-limiting examples. The pump 36 may generally include one or more pumps including, but not limited to, a rotary vane vacuum pump, a diaphragm vacuum pump, liquid ring vacuum pump, scroll vacuum, and a turbomolecular vacuum pump.

In some implementations, the chamber endplate 140a is coupled to the plasma source 38, which may transfers the plasma 40a into the cavity 111 of the vacuum chamber 110. In some implementations, the plasma source 38 may include one or more plasma sources that each generate a plasma that is injected into the cavity 111. The plasma source 38 may generally include a gas source and an electric field source to ionize the gas and generate a plasma. For example, the plasma source 38 may supply hydrogen including deuterium and/or helium (or other heavier elements) and a pair of electrodes coupled to a voltage supply. In some implementations, the plasma source 38 may be configured to generate a plasma within the cavity 111 of the vacuum chamber 110. For example, the plasma source 38 may include a gas source directly coupled to the chamber endplate 140a to supply gas into the cavity 111 and an electric field source coupled to the vacuum chamber 110 to ionize the gas and form the plasma 40a within the cavity 111. The vacuum chamber system 100a may further include the magnetic field source 34 disposed around the chamber walls 120-1 through 120-3 to generate a magnetic field to confine and/or shape the plasma 40a. In some implementations, the magnetic field source 34 may include, for example, one or more electromagnetic coils disposed around the vacuum chamber 110 to generate one or more magnetic fields into the cavity 111 (e.g., see magnetic field lines 42-1, 42-2, and 42-3). More generally, the magnetic field source 34 may include various types of devices and/or components to generate a magnetic field including, but not limited to, one or more permanent magnets (e.g., a magnetic ring, an array of magnets disposed around the vacuum chamber 110) and one or more electromagnets (e.g., the electromagnetic coils, a current flowing through an electrically conductive plate). The magnetic fields may be used to modify the shape of the plasma 40a. For example, the magnetic field source 34 may confine and/or compress the plasma 40a. In some implementations, the vacuum chamber system 100a may include an electric field source to control and modify the properties of the plasma 40a in place of the magnetic field source 34 or together with the magnetic field source 34.

Although the vacuum chamber system 100a is shown containing the plasma 40a, it should be appreciated that other substances may be disposed in the cavity 111. More generally, the plasma source 38 may be a specimen source 38 that provides the desired substance to the vacuum chamber 110. For example, the specimen source 38 may be a gas source that provides an inert gas (e.g., argon). The inert gas may be used to control the stoichiometry of a film deposited using, for example, pulsed laser deposition. In another example, the specimen source 38 may be a load lock chamber designed to transfer a solid object from ambient into the cavity 111 without breaking vacuum. The load lock chamber may be used, for example, to transfer a silicon wafer into the cavity 111 for materials deposition or etching.

The vacuum chamber 110 and the constituent parts forming the vacuum chamber 110 may have various geometries. For example, FIG. 3A shows the vacuum chamber 110 may have an elongated shape, such as a cylinder or a rectangular prism. The chamber walls 120 may have a rotationally symmetric shape with a cross-sectional shape that includes, but is not limited to, a circle, an ellipse, a square, a rectangle, or any combinations of the foregoing. In FIG. 3A, the top and bottom portions of each of the chamber walls 120-1, 120-2, and 120-3 may correspond to the same component (e.g., the chamber wall 120 is a cylinder) or different components (e.g., the chamber walls 120 are multiple plates attached together). The cross-sectional shape of the chamber walls 120 may also vary along its length. For example, the chamber wall 120 may be conical in shape. The shape of the endplates 140a and 140b may also conform with the cross-sectional shape of the chamber walls 120. For instance, the chamber walls 120 and the endplates 140a and 140b may be circular, square, or rectangular in shape. In some implementations, the vacuum chamber system 100a may alternatively include a vacuum chamber that is spherical, toroidal, or cubic in shape.

Additionally, the vacuum chamber 110 may define a cavity 111 with a nominal characteristic width of about, for example, 0.5 m to 3 m, including all values and sub-ranges in between. For example, the nominal characteristic width may be a diameter if the cavity 111 has a circular cross-sectional shape or a diagonal if the cavity 111 has a square cross-sectional shape. More generally, the nominal width of the cavity 111 may range between, for example, about 0.1 m and about 10 m, including all values and sub-ranges in between. It should be appreciated the dimensions of the vacuum chamber 110 disclosed herein are non-limiting examples and that, more generally, the various inventive concepts disclosed herein, such as application of a shield assembly, may be applied to smaller or larger sized vacuum chambers. The term “about,” when used to describe the dimensions of the vacuum chamber 110, is intended to cover manufacturing tolerances. For example, “about 1 m” may correspond to the following dimensional ranges: 0.99 to 1.01 m (+/−1% tolerance), 0.992 to 1.008 m (+/−0.8% tolerance), 0.994 to 1.006 m (+/−0.6% tolerance), 0.996 to 1.004 m (+/−0.4% tolerance), 0.998 to 1.002 m (+/−0.2% tolerance), including all values and sub-ranges in between.

The chamber walls 120 and the endplates 140a and 140b may be formed from various materials including, but not limited to, a metal (e.g., steel, aluminum) and a ceramic (e.g., silicon dioxide (SiO₂), aluminum oxide (Al₂O₃), boron nitride (BN), boron carbide (BC), silicon nitride (SiN), aluminum nitride (AlN)), and any combinations of the foregoing (e.g., 50% SiO₂:50% BN). In some implementations, the chamber walls 120 and the endplates 140a and 140b may be preferably formed from a ceramic material that is transmissive to electromagnetic fields emitted by the magnetic field source 34 and/or the electric field source.

FIGS. 3B-3D show each of the shield assemblies 300a as disposed between a gasket of a gasket assembly and the plasma 40a to reduce or, in some instances, mitigate the transmission of charged particles from the plasma 40a that interact (e.g., sputter) with the gasket and, in turn, generate contaminants. The shield assemblies 300a also reduce or, in some instances, mitigate the transmission of contaminants in the event that contaminants are generated. Specifically, FIG. 3B shows the gasket 22 in the gasket assembly 200a-2 is partially disposed in an exterior portion of a gap 160a formed between the chamber wall 120-1 and the chamber endplate 140a. The shield assembly 300a is at least partially disposed in an interior portion of the gap 160a (i.e., the portion of the gap 160a abutting the cavity 111). The gasket 22 and the shield assembly 300a each forms a closed loop that extends along the entirety of the gap 160a. In this manner, the gasket 22 seals the interface between the chamber wall 120-1 and the chamber endplate 140a and the shield assembly 300a protects the gasket 22 and limits the transmission of contaminants to the plasma 40a. The gasket assembly 200a-2 is arranged in a similar manner as the gasket assembly 200a-1 to seal an interface formed between the chamber wall 120-3 and the chamber endplate 140b.

In some implementations, the shield assembly 300a may be fully disposed within the gap 160a. More generally, a portion of the shield assembly 300a may protrude into the cavity 111 when the vacuum chamber 110 is fully assembled. The shield assembly 300a may further be self-supported within the gap 160a. This may be accomplished, in part, by compressing the shield assembly 300a between the chamber wall 120-1 and the chamber endplate 140a to achieve a compressive fit, as discussed in more detail below. Additionally, the shield assembly may also be configured act as a mechanical spring that is retained within the gap 160a, for example, due to an internal restoring force that extends the shield assembly outwards towards the gasket 22, as discussed in more detail below.

FIG. 3C shows the gasket 22 in the gasket assembly 200b-1 is partially disposed in an exterior portion of a gap 160b formed between the chamber walls 120-1 and 120-2 to form a scal between the chamber walls 120-1 and 120-2 and a shield assembly 300a at least partially disposed in an interior portion of the gap 160b to protect the gasket 22. The gasket assembly 200b-2 is arranged in a similar manner as the gasket assembly 200b-1 to seal an interface formed between the chamber walls 120-2 and 120-3. FIG. 3D shows the gasket 22 in the gasket assembly 200c is disposed in a gap 160c formed between the window 144 and the baseplate 142 of the chamber endplate 140b to form a seal around the window 144. The shield assembly 300a in the gasket assembly 200c is further partially disposed within the gap 160c to protect the gasket 22.

The shield assembly 300a may generally be formed from multiple ceramic fibers 310. The ceramic fibers 310 may be formed from a ceramic material which, when compared to elastomers, is more resistant to sputtering and degradation when exposed to charged particles ejected from a plasma, produces fewer contaminants that react with the plasma in an undesirable manner (e.g., fewer carbon or fluorine contaminants), and/or is stable at room temperature and higher temperatures, e.g., 20° C. to 300° C., including all values and sub-ranges in between. It should be appreciated that the temperature range at which the material is stable is a non-limiting example and that the ceramic fibers may be formed from a material that is stable at lower or higher temperatures.

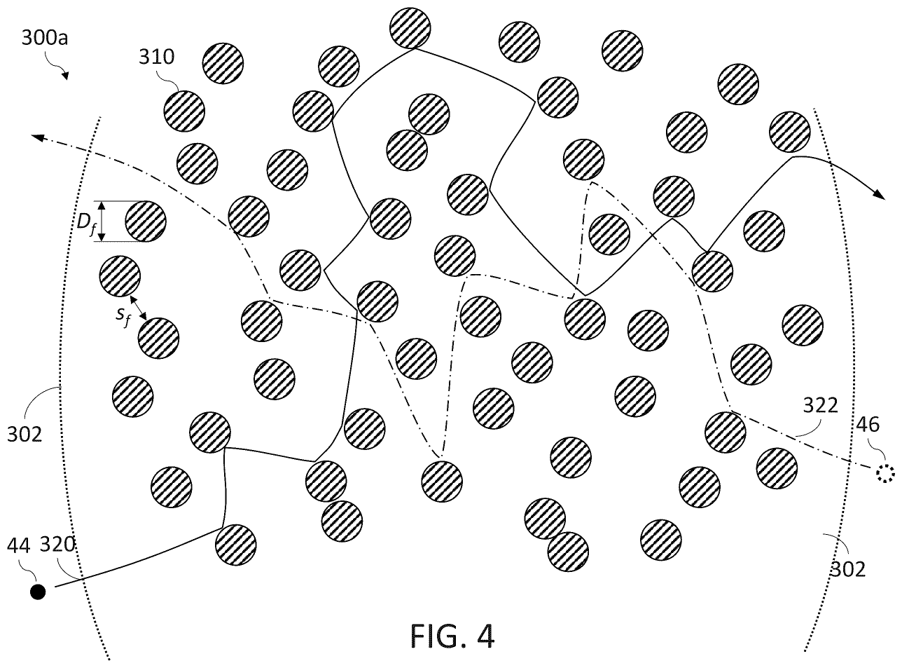

Additionally, FIG. 4 shows the ceramic fibers 310 may also be arranged in a packed structure where individual fibers 310 are either in physical contact with other fibers 310 or separated from other fibers 310 by a small interstitial space. It should be appreciated that the interstitial spaces between the fibers 310 are also evacuated by the pump 36 and thus, may be at a pressure similar to or the same as the cavity 111. The packed structure may further define an envelope 302 (i.e., the outermost boundary) containing the ceramic fibers 310 of the shield assembly 300a.

The ceramic fibers 310 and the interstitial spaces between the ceramic fibers 310 may form a tortuous trajectory that reduces or, in some instances, mitigates the transport of charged particles ejected from the plasma 40a and/or the transport of contaminants towards the plasma 40a. Specifically, a charged particle or a contaminant entering the shield assembly 300a would reflect off the ceramic fibers 310 multiple times before passing through the shield assembly 300a assuming the charged particle or contaminant does not dissipate its energy within the shield assembly 300a. For example, FIG. 4 shows a charged particle 44 may follow the tortuous trajectory 320 through the shield assembly 300a. Similarly, a contaminant 46 may follow the tortuous trajectory 322 through the shield assembly 300a. Each time the charged particle or contaminant strikes a ceramic fiber 310, however, some or all of the energy (e.g., the kinetic energy) of the charged particle 44 or the contaminant 46 may be absorbed by the ceramic fiber 310. In other words, the charged particle 44 or the contaminant 46, on average is reflected a finite number of times before losing its energy and depositing on the ceramic fibers 310. Generally, the charged particles and contaminants may each reflect off the ceramic fibers 310 hundreds or thousands of times before passing through the shield assembly 300a.

The shield assembly 300a may generally include a sufficient number of ceramic fibers 310 such that the average number of reflections for a charged particle 44 or a contaminant 46 to pass through the shield assembly 300a is larger than the average number of reflections the charged particle 44 or the contaminant 46 before its energy is dissipated. In other words, the shield assembly 300a may appreciably reduce or, in some instances, effectively prevent the transport of charged particles 44 towards the gasket. Even if a charged particle 44 makes it through the shield assembly 300a and generates a contaminant 46, the shield assembly 300a similarly reduces, mitigates, or effectively prevents transport of the contaminant 46 back towards the plasma 40a.

It should be appreciated that the use of the shield assembly 300a in the different gasket assemblies of the vacuum chamber system 100a is a non-limiting example. More generally, different shield assemblies with more or fewer ceramic fibers 310 may be used with different gaskets 22 in the vacuum chamber 110. For example, the magnetic field may be oriented more parallel with some of the gaps in the vacuum chamber 110 (e.g., see the magnetic field line 42-1 in the gaps 160a at the respective ends of the vacuum chamber 110), which may expose the gaskets 22 disposed in those gaps to more charged particles 44. Thus, a shield assembly with a higher number of ceramic fibers 310 and/or multiple shield assemblies may be used in those respective gaps to provide more shielding of those gaskets 22. In another example, if the magnetic field is oriented more perpendicular with a gap of the vacuum chamber 110, the gasket 22 in that gap may be exposed to fewer charged particles 44. Thus, a shield assembly with a lower number of ceramic fibers 310 and/or fewer shield assemblies may be used in that gap.

In this manner, the shield assembly 300a may appreciably reduce the exposure of components in the vacuum chamber system 100a that are sensitive to the charged particles 44 ejected by the plasma 40a, such as the gaskets. For instance, a charged particle 44-1 may be blocked by the shield assembly 300a in the gasket assembly 200a-1 even if the magnetic field line 42-1 passes through the shield assembly 300a and the gasket 22. Similarly, a charged particle 44-2 traveling along the magnetic field line 42-2 may be blocked by the shield assembly 300a in the gasket assembly 200b-1. A charged particle 44-3 traveling along the magnetic field line 42-3 may also be blocked by the shield assembly 300a in the gasket assembly 200c.

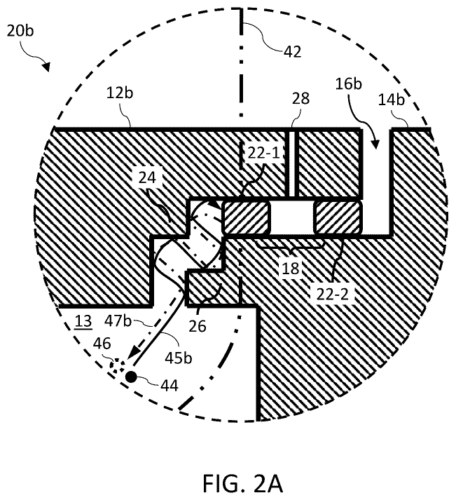

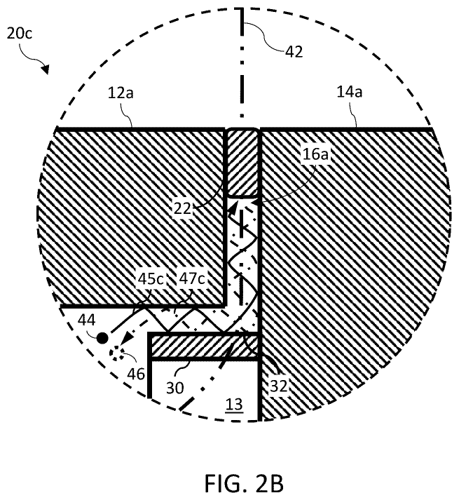

The incorporation of the shield assemblies 300a allows the use of conventional gaskets formed from materials, such as elastomers (e.g., Buna-N, silicone, fluorocarbon, perfluorocarbon) or metals (e.g., copper, aluminum), while appreciably reducing the generation of contaminants. Additionally, the chamber walls 120 and/or the chamber endplates 140a and 140b may maintain a relatively simple geometry to facilitate the formation of a seal unlike, for example, the gasket assembly 20b shown in FIG. 2A.

The shield assemblies 300a may generally be shaped to accommodate various-sized gaps with various geometries formed in the vacuum chamber 110. This may be accomplished, in part, by the ceramic fibers 310 having a geometry that provides appreciably greater mechanical compliance compared to, for example, the ceramic ring 30 in the gasket assembly 20c shown in FIG. 2B. For example, the mechanical compliance of each ceramic fiber 310 may be characterized by the bending stiffness of the fiber (K), which may be generally defined as the ratio of the applied load (e.g., a moment, a force) divided by the deflection of the fiber (e.g., angular deflection, linear deflection). For a fiber with a uniform cross-section along its length, the bending stiffness may be proportional to the Young's modulus (E) of the ceramic material used to form the fiber and the moment of inertia (I) about a neutral axis of the fiber and inversely proportional to the length of the fiber (L). Depending on the loads applied to the fiber and type of deflection considered, the bending stiffness may be inversely proportion to the length raised to a higher power (e.g., L², L³). The neutral axis is the axis along which the stresses directed along the length of the fiber 310 have a magnitude equal to 0 Pa), which typically coincides with the centroid of the cross-section of the fiber. The moment of inertia about the neutral axis generally scales with a characteristic width of the fiber raised to the fourth power (e.g., D⁴ for a fiber with a circular cross section).

The following is a non-limiting example showing the difference in mechanical compliance between the ceramic fiber 310 and a ceramic beam with cross-sectional dimensions comparable to a typical ceramic ring. In this example, the mechanical compliance is characterized by the bending stiffness K_{F}, defined as the ratio of the applied force divided by the linear deflection, which equals K_{F}=3EI/L³. It is assumed (i) the ceramic fiber 310 and a ceramic beam are clamped at one end and the force is applied at the free end, (ii) the ceramic fiber 310 and the ceramic beam are each made SiO₂, which has a Young's modulus (E) equal to about 70 GPa, (iii) both the ceramic fiber 310 and the ceramic beam has a length (L) of 1 m, and (iv) both the ceramic fiber 310 and the ceramic beam has a uniform circular cross-section. It is further assumed the ceramic fiber 310 has a diameter (D₁) of 100 μm and the ceramic beam has a diameter (D₂) of 1 mm, which is typical for ceramic rings. Based on the above, the bending stiffness K_{F,1} of the ceramic fiber 310 is approximately 10⁻⁶ N/m while the bending stiffness K_{F,2} of the ceramic beam is approximately 10⁻² N/m. In other words, if the same force is applied to the ceramic fiber 310 and the ceramic beam, the deflection of the ceramic fiber 310 is 10,000 times greater than the ceramic ring.

As shown in the above example, the bending stiffness of the ceramic fibers 310 may be appreciably smaller than a ceramic ring due to the relatively smaller width and the relative larger length of each fiber 310. The smaller bending stiffness of the ceramic fibers 310 allows the fibers 310 to readily bend without fracture. Said in another way, the compressive and tensile stresses applied to the fiber 310 when the fiber 310 is bent is appreciably smaller than, for example, the ceramic ring 30 due, in part, to the smaller cross-sectional width of the fiber 310 compared to the ceramic ring 30. The largest tensile and compressive stresses are generally located furthest from the neutral axis, which typically corresponds to the outer surface of the fiber 310. For the shield assembly 300a, the distance between the outer surface of the fiber 310 and its neutral axis may be on the order of microns. In contrast, the distance between the outer surface of the ceramic ring 30 and its neutral axis is typically on the order of millimeters, resulting in stresses that are orders of magnitude larger than the fibers 310.

In some implementations, the ceramic fibers 310 may each have a diameter, Dj, that ranges between about 0.1 μm and about 100 μm, including all values and sub-ranges in between. The ceramic fibers 310 may further be separated by an average nearest neighbor distance, sy, that ranges between about 0.1 μm and about 100 μm, including all values and sub-ranges in between. It should be appreciated, however, the separation distance between neighboring ceramic fibers 310 may vary along the respective lengths of the ceramic fibers 310 where at least some portions of neighboring fiber strands are in physical contact with one another, and other portions separated by distances greater than 100 μm. Generally, the separation distance between neighboring fibers along at least a portion of the fibers may range between about 0 μm and about 100 μm, including all values and sub-ranges in between. The shield assemblies 300a may also be formed from ceramic fibers 310 that have different sizes so long as a tortuous trajectory is formed to inhibit the transport of various contaminants. It should be appreciated the size and separation distance of the ceramic fibers 310 may vary beyond the range of values described above as long as the ceramic fibers 310 are of sufficient quantity along the depth of the shield assembly 300a to create tortuous trajectories that generally prevents a charged particle or contaminant from passing through the shield assembly 300a before being drained of energy.

The ceramic fibers 310 may also have a length that ranges between about 0.1 m to about 100 m, including all values and sub-ranges in between. In some implementations, the length may depend on the size of the chamber and the length of the gap to be covered. The envelope 302 of the shield assembly 300a may generally have a thickness, tᵣ, that ranges between about 0.1 mm to about 50 mm, including all values and sub-ranges in between. If the average diameter of the fibers 310 is about 10 μm, the average number of fibers 310 disposed between the plasma 40a and the gasket may range between about 10 to about 15,000, including all values and sub-ranges in between. The term “about,” when used to describe the dimensions of the ceramic fibers 310, is intended to cover manufacturing tolerances. For example, “about 10 μm” may correspond to the following dimensional ranges: 9.9 to 10.1 μm (+/−1% tolerance), 9.92 to 10.08 μm (+/−0.8% tolerance), 9.94 to 10.06 μm (+/−0.6% tolerance), 9.96 to 10.04 μm (+/−0.4% tolerance), 9.98 to 10.02 μm (+/−0.2% tolerance), including all values and sub-ranges in between. It should be appreciated that the foregoing dimensional ranges are non-limiting. Moreover, the manufacturing tolerances may be larger depending on the various manufacturing processes used to form the ceramic fibers 310 as known in the art.

The ceramic fibers 310 may generally be formed from nonporous ceramic materials that do not outgas at vapor pressures ranging from about 10⁻³ Torr to about 10⁻⁸ Torr, including all values and sub-ranges in between. It should be appreciated the vapor pressures are non-limiting examples and that, more generally, nonporous ceramic materials may be chosen that do not outgas at other vapor pressures depending on the operating environment within the vacuum chamber system. Various ceramic materials may be used to form the ceramic fibers 310 including, but not limited to, silicon dioxide (SiO₂), aluminum oxide (Al₂O₃), boron nitride (BN), boron carbide (BC), silicon nitride (SiN), aluminum nitride (AlN), and any combinations of the foregoing (e.g., 50% SiO₂:50% BN). In some implementations, the ceramic fibers 310 may be formed from the same material as the chamber walls 120 and/or the chamber endplates 140a and 140b, in part, so that the contaminants sputtered off the shield assembly are the same as the contaminants sputtered off the chamber walls and/or the chamber endplates. In some implementations, such as vacuum chambers using magnetic fields to confine the plasma, a dielectric material may be preferred (many ceramics are dielectrics). In some implementations, the ceramic fibers 310 may be formed from materials that provide similar material properties as the chamber walls 120 and/or the chamber endplates 140a and 140b. For example, the ceramic fibers 310 may be formed from a material with a similar dielectric permittivity or magnetic permeability as the chamber walls 120 and/or the chamber endplates 140a and 140b. In another example, the ceramic fibers 310 may be formed from a material with similar thermal properties (e.g., thermal conductivity, coefficient of thermal expansion) as the chamber walls 120 and/or the chamber endplates 140a and 140b.

Based on the various materials and dimensions above, the bending stiffness Kr of the ceramic fiber 310 may range from about 10⁻³ N/m to about 10-25 N/m, including all values and sub-ranges in between. The term “about,” when used to describe the bending stiffness of the ceramic fibers 310, is intended to cover variances in the composition and dimensions of the ceramic fibers during manufacture. For example, “about 10⁻⁶ N/m” may correspond to the following ranges: 0.99·10⁻⁶ to 1.01·10⁻⁶ N/m (+/−1% tolerance), 0.98·10⁻⁶ to 1.02·10⁻⁶ N/m (+/−2% tolerance), 0.96·10⁻⁶ to 1.04·10⁻⁶ N/m (+/−4% tolerance), 0.94·10⁻⁶ to 1.06·10⁻⁶ N/m (+/−6% tolerance), 0.92·10⁻⁶ to 1.08·10⁻⁶ N/m (+/−8% tolerance), 0.9·10⁻⁶ to 1.1·10⁻⁶ N/m (+/−10% tolerance), including all values and sub-ranges in between. It should be appreciated that the foregoing ranges of the bending stiffness are non-limiting and that the resultant range of values may be larger depending on the various manufacturing processes used to form the ceramic fibers 310 as known in the art.

In some implementations, the ceramic fibers 310 may be formed from high purity ceramic materials. For example, the ceramic fibers 310 may be formed from SiO₂ where the SiO₂ mass fraction is greater than or equal to about 0.98. In some implementations, the SiO₂ mass fraction may be greater than or equal to about 0.9995. In another example, the ceramic fibers 310 may be formed from 50:50 SiO₂ and BN where the mass fractions of SiO₂ and BN are between about 0.4 and 0.60, including all values and sub-ranges in between. In some implementations, the mass fractions of SiO₂ and BN may each be about 0.5. In some implementations, the mass fraction of the impurities in the ceramic material used to form the ceramic fibers 310 may be less than or equal to 0.05. It should be appreciated that other mixtures are possible and depend, in part, on the application and desired material properties of the ceramic fibers 310. It should also be appreciated that the mass fractions of the constituent materials described above are non-limiting examples. For some applications, the ceramic fibers may be formed of lower purity ceramic materials. For example, in a plasma composed of higher-atomic mass elements, the plasma may be more tolerant to contaminants originating from the ceramic fibers. In another example, in a hydrogen plasma, lower purity ceramic materials may still be used particularly if the impurities are lower atomic mass elements, such as silicon, boron, nitrogen, or oxygen. Moreover, lower purity ceramic materials may be used provided the generation of contaminants does not appreciably degrade the shield assembly over time. The term “about,” when used to describe the purity of the ceramic fibers 310, is intended to cover variances in the composition of the ceramic fibers during manufacture. For example, “about 0.9995” may correspond to the following ranges: 0.9994 to 0.9996 (+/−0.01% tolerance), 0.9993 to 0.9997 (+/−0.02% tolerance), 0.9992 to 0.9998 (+/−0.03% tolerance), 0.9991 to 0.9999 (+/−0.04% tolerance), 0.999 to 1.00 (+/−0.05% tolerance), including all values and sub-ranges in between. However, it should be appreciated that the foregoing ranges of the purity of the ceramic fibers 310 are non-limiting and that the range of values may be larger depending on the various manufacturing processes used to synthesize and process the ceramic material.

In some implementations, the composition and/or mass fraction of the constituent materials forming the ceramic fibers 310 may also vary based on the impact of contaminants that may be generated from the ceramic fibers 310. For example, in a hydrogen plasma, the presence of higher atomic mass contaminants, such as tungsten, may absorb or radiate away energy from the plasma. Thus, it may be preferable for the ceramic fibers 310 to be formed of lower atomic mass elements, such as silicon, boron, nitrogen, or oxygen, so that the contaminants generated are lower atomic mass contaminants, which are less disruptive to the hydrogen plasma. In another example, in a plasma composed of higher-atomic mass elements, such as in the production of novel isotopes, the plasma may be less sensitive to the presence of higher atomic mass contaminants. Thus, the ceramic fibers 310 may be formed of low and/or high atomic mass elements.

Additionally, the density of the shield assembly may generally depend on the density of the ceramic material and the volume fraction of the fibers 310 relative to the volume fraction of the interstitial space between the fibers. In one example, ceramic fibers formed from only SiO₂ may have a density of about 1060 kg/m³, which is lower than the density of bulk SiO₂ (˜2410 kg/m³) due to the presence of interstitial spaces between the fibers. In other words, the density of the shield assembly 300a depends on the product of the density of SiO₂ and the volume fraction of the fibers 310 contained within the envelope 302. It should be appreciated that the density of the shield assembly may vary based on the ceramic material used to form the fibers. It should also be appreciated that the density of the ceramic fibers may change during preparation and installation, for example, when the plastic coating or greases are removed or when the fibers are packed into a gap in the vacuum chamber. In some implementations, the density of the shield assembly may be as low as 10% of the density of the bulk ceramic. It should be appreciated the density of the shield assembly is non-limiting and that, more generally, any density may be used provided the shield assembly forms tortuous trajectories that cause the particles to exhaust its energy before passing through the shield assembly.

The mechanical compliance of the ceramic fibers 310 may allow the fibers 310 to be wound or bundled together to form a discrete component, such as a rope, a tube, or a sheet. For example, the fibers 310 may be wound into a yarn and the yarn, in turn, may be wound into a rope with a braided structure. In some implementations, the fibers 310 may be arranged parallel to one another. In some implementations, the fibers 310 may be intertwined to form a more random structure that reduces the transport of the charged particles and the contaminants through the shield assembly. The fibers 310 may further be sintered together to prevent separation of the fibers 310 where one fiber 310 is bonded to another fiber 310 along at least a portion of its length. In some implementations, the fibers 310 may be bonded using an adhesive (e.g., a ceramic-based adhesive). For example, an adhesive with a ceramic filler and a binder may bond one or more fibers 310 together, after which the binder can be removed such as, for example, by exposing the fibers 310 to sufficiently high temperatures to burn off the binder.

The discrete component, in turn, may be cut to a desired size to form the shield assembly 300a and the shield assembly 300a may then be fitted to a particular gap in the vacuum chamber 110. The shape and/or dimensions of the gaps may vary based on the parts of the vacuum chamber 110 defining the gap. For example, each shield assembly 300a in the vacuum chamber system 100a may be cut from the same continuous spool of rope of ceramic fibers 310 with different lengths according to the different gaps of the vacuum chamber 110.

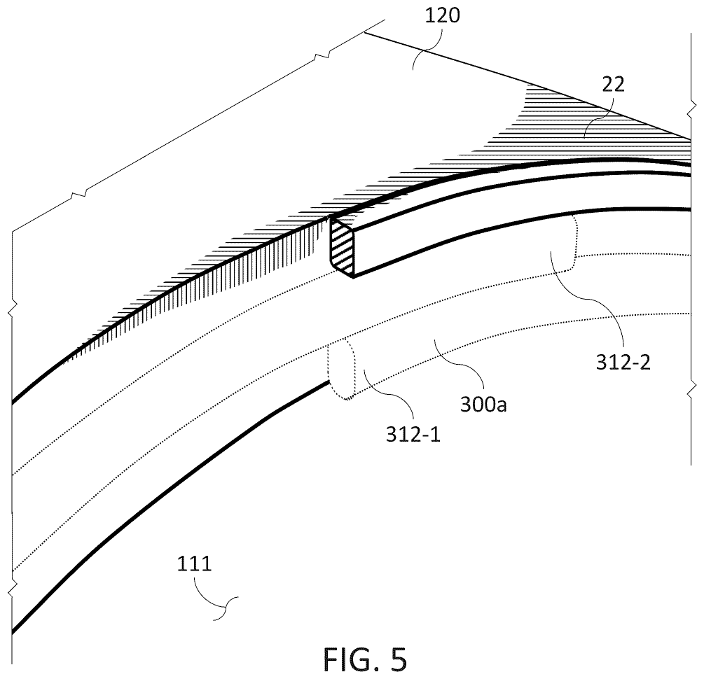

FIG. 5 shows a cutaway view of the interface between adjoining chamber walls 120 (e.g., the chamber walls 120-1 and 120-2) where the chamber wall 120 is cylindrical in shape. As shown, the gasket 22 and the shield assembly 300a may extend along the side of the chamber wall 120 forming the gap 160b. In particular, the ceramic fibers 310 forming the shield assembly 300a may be shaped as a rope that is arranged to form a circular closed loop. The gasket 22 may be a ring that is positioned in concentric alignment with the shield assembly 300a. It should be appreciated that the circular closed-loop geometry is non-limiting. In some implementations, the ceramic fibers 310 may be divided into separate segments that, when assembled, collectively form a closed-loop structure. In some implementations, the ceramic fibers 310 may form part of a tape (e.g., the shield assembly 300c) that may be a rectangular sheet that is adhered to the interior surfaces of the vacuum chamber 110 to cover the gap 160b.

In some implementations, the shield assembly 300a may be arranged where the respective ends 312-1 and 312-2 of the shield assembly 300a extend past one another such that end portions of the shield assembly 300a overlap one another to eliminate gaps that may otherwise be formed between the ends 312-1 and 312-2 if the ends 312-1 and 312-2 abut each other. Alternatively, the ends 312-1 and 312-2 may be fused together to form an enclosed ring. In some implementations, the shield assembly 300a may include multiple concentric loops formed either from a single cut section (e.g., a rope) arranged in a continuous spiral and/or multiple cut sections that are arranged in concentric alignment with one another. The cut sections could each be individually long enough to form a single concentric loop, or shorter than a full loop.

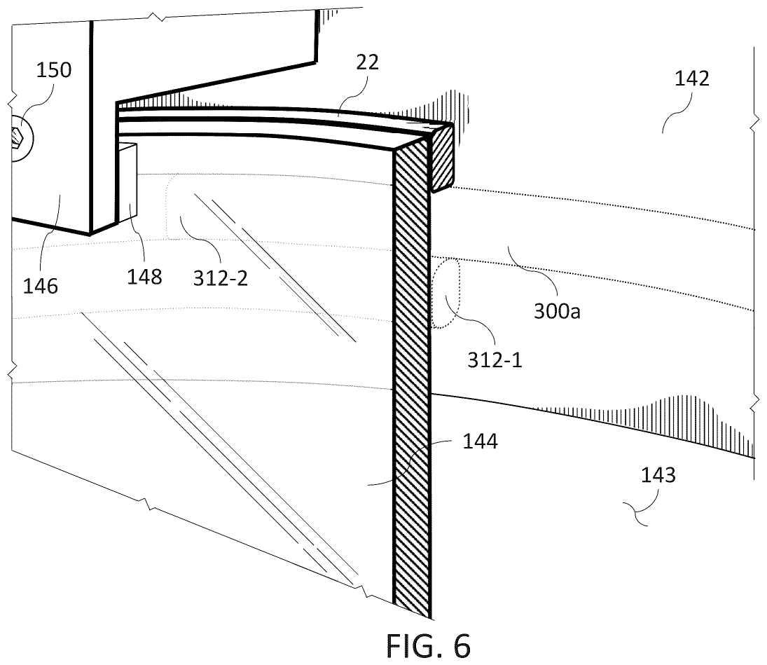

In another example, FIG. 6 shows a cutaway view of the interface between the window 144 and the baseplate 142 of the chamber endplate 140b. As shown, the window 144 may be pressed onto the base plate 142 via a clamp 146. The clamp 146 includes a deformable pad 148 to provide a cushioned contact the window 144 and a fastener 150 to tighten the clamp 146 against the window 144. In this example, the window 144 and the baseplate 142 may each be circular in shape and the baseplate 142 may further define a circular aperture 143. The gasket 22 may extend around the periphery of the window 144 and the shield assembly 300a may be disposed around the aperture 143. As shown, the ends 312-1 and 312-2 may again extend past one another such that the shield assembly 300a forms a circular closed loop.

### Additional Examples of Ceramic Fiber Shield Assemblies

As described above, the shield assembly 300a may be formed as a rope with ceramic fibers 310 that are distributed substantially evenly or evenly across the cross-section of the envelope 302. However, it should be appreciated that the ceramic fibers 310 may be arranged in other shapes and forms to protect other components in the vacuum chamber system 100a.

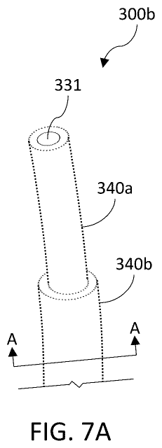

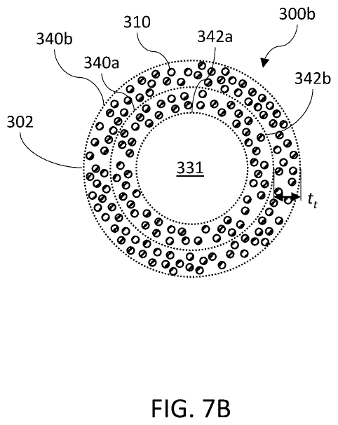

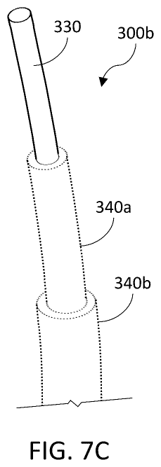

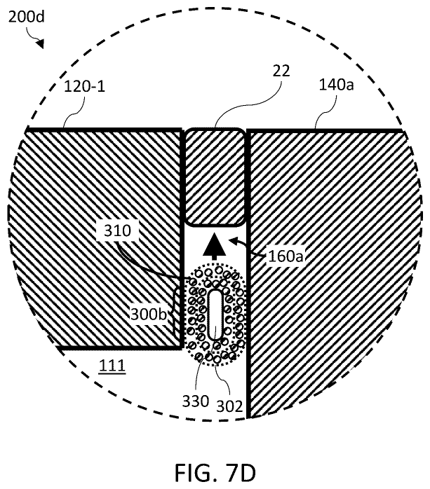

In another example, FIGS. 7A and 7B show a shield assembly 300b where the ceramic fibers 310 are arranged in the shape of a tube, which may be used to form a sheath to surround and protect a component. As shown, the ceramic fibers 310 may surround and define a cavity 331 into which the component may be disposed. In some implementations, the shield assembly 300b may include multiple tubes of ceramic fibers 310 forming multiple layers of ceramic fibers 310 to protect the component. Said in another way, the multiple tubes of ceramic fibers 310 may be arranged in a telescoping manner. In some implementations, the multiple tubes may be concentrically aligned with respect to one another. For example, the shield assembly 300b may include a first tube 340a defining a cavity 342a to contain the component and a second tube 340b defining a cavity 342b so that the component and the first tube 340a may be inserted together into the cavity 342b of the second tube 340b. Each of the tubes 340a and 340b are formed from an assembly of ceramic fibers 310.

The ceramic fibers 310 may form a tortuous trajectory that limits not only the transport of charged particles 44 and contaminants 46 across the shield assembly 300a, but also limits the transport of charged particles 44 and contaminants 46 to and from the cavity 331. In this manner, the shield assembly 300b may protect various components disposed within the cavity 331 that may otherwise produce unwanted contaminants in the cavity 111 if directly exposed to the plasma 40a, especially components formed from metal and/or polymer. In turn, the generation of contaminants from the components may be reduced. Said another way, the shield assembly 300b permits the addition/use of components into the vacuum chamber 110 that traditionally are not included in previous vacuum chamber systems. The component may be various mechanical and/or electrical components and/or devices including, but not limited to, the gasket 22, a mechanical component (e.g., a rod made of a metal, a polymer, or fiberglass, bolt head), an electrical wire, a camera, and a sensor (e.g., a magnetic field or flux sensor, a plasma density sensor, a temperature sensor, a Langmuir probe, sensors to detect neutrons, alpha particles, and/or electrons) to monitor various aspects of the vacuum chamber system 100a and/or the plasma 40a during operation. The component may be further formed from various materials including, but not limited to, ceramics (e.g., enamel), metals (e.g., copper, aluminum), polymers (e.g., polyethylene, polyethylene terephthalate, polypropylene, rubber), or any combinations of the foregoing.

FIGS. 7C and 7D show one example application of the shield assembly 300b where the shield assembly 300b is used as part of a gasket assembly 200d to protect the gasket 22. Specifically, FIG. 7C shows a rod 330 may be inserted into the cavity 331 formed by the first tube 340a. The rod 330 may act as a spring to retain the shield assembly 300b in the gap 160a. In some implementations, the rod may be formed from fiberglass (e.g., G-10 fiberglass).

FIG. 7D shows the gasket assembly 200d is used in place of the gasket assembly 200a-1. However, it should be appreciated any of the gasket assemblies 200a-2, 200b-1, 200b-2, and 200c may also include the shield assembly 300b in place of the shield assembly 300a. When the shield assembly 300b is inserted into the gap 160a between the chamber wall 120-1 and the chamber endplate 140a, the rod 330 may be at least partially deformed elastically, which, in turn, gives rise to an internal restoring force. For example, the rod 330 may initially be substantially straight or straight in shape and bent together with the ceramic fibers 310 to form a circular closed loop during assembly of the vacuum chamber 110. If the shield assembly 300b is not mechanically constrained, the internal restoring force generated would return the shield assembly 300b approximately to its original straight shape. When the shield assembly 300b is installed into the vacuum chamber 110, however, the shield assembly 300b is mechanically constrained by, for example, the gasket 22, the chamber wall 120-1, and/or the chamber endplate 140a. The mechanical constraints imposed on the shield assembly 300b maintain the desired circular closed loop geometry. The internal restoring force, however, may act in an outwards direction away from the cavity 111 (see black arrow in FIG. 7C), thus retaining the shield assembly 300b in the gap 160a.

In another example, the shield assembly 300b may contain one or more electrical wires to transmit electrical power and/or provide data communications from an electrical feedthrough in the vacuum chamber system 100a to sensors deployed within the cavity 111 of the vacuum chamber 110. In yet another example, multiple shield assemblies 300b that each contain a magnetic field sensor (not shown) may be disposed in the cavity 111 to provide multiple measurement points in the cavity 111 to quantify the spatial distribution of the magnetic field generated by the magnetic field source 34.

Each tube 340a and 340b may have a thickness, tₜ, that ranges between about 0.1 mm and about 50 mm, including all values and sub-ranges in between. It should be appreciated that the foregoing dimensional ranges is a non-limiting example. In some implementations, the thickness of the shield assembly 300b may vary by including multiple tubes of ceramic fibers 310 with varying lengths. For example, the thickness of the shield assembly 300b may be made thicker for portions of the shield assembly 300b that are subjected to a higher flux of charged particles 44 from the plasma 40a and thinner for portions of the shield assembly 300b at are subjected to a lower flux of charged particles 44 from the plasma 40a.

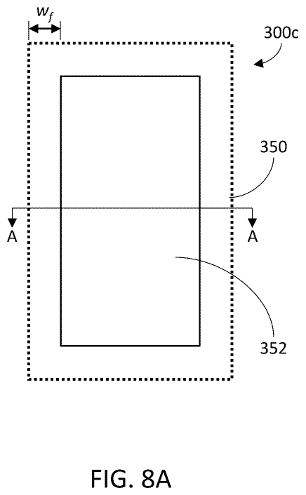

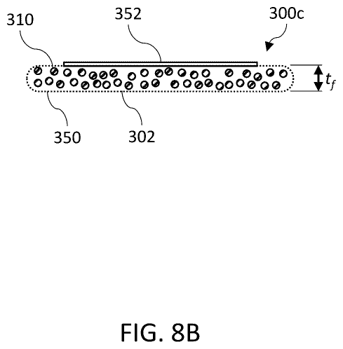

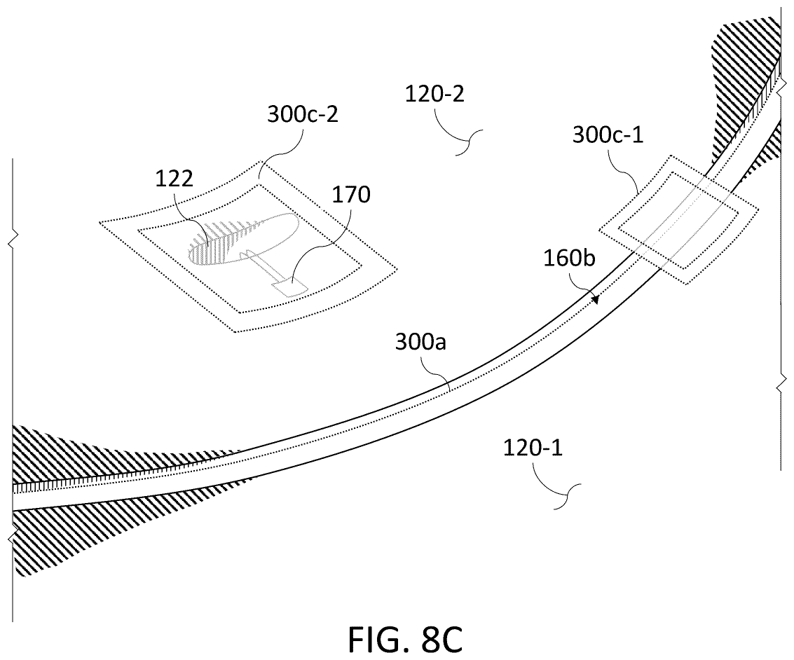

FIGS. 8A and 8B show another example shield assembly 300c in the form of a flat sheet. In some implementations, the shield assembly 300c may further include an adhesive layer 352 to attach, for example, the shield assembly 300c to the interior surfaces of the vacuum chamber 110 and/or form a protective enclosure for one or more components covered by the shield assembly 300c. For example, the shield assembly 300c may facilitate attachment of a sensor or a wire to the interior surfaces of the chamber walls 120. In another example, multiple shield assemblies 300c may be attached together to form a protective enclosure as an alternative to the shield assembly 300b. In yet another example, the shield assembly 300c may be applied onto components mounted to a port on the vacuum chamber 110 (e.g., electrical connectors on an electrical feedthrough). This may be achieved, for example, by bonding the adhesive 352 of one shield assembly 300c to the adhesive 352 of another shield assembly 300c. The adhesive 352 may be various types of adhesives, including, but not limited to, acrylic, polyimide, and/or a ceramic-based adhesive, including combinations thereof.

As shown, the ceramic fibers 310 may be arranged in the shape of a film. In some implementations, the ceramic fibers 310 may be aligned substantially parallel to each other, where the fibers 310 are oriented along a single axis. For example, the film may be formed by cutting the first tube 340a and/or the second tube 340b longitudinally and unfolding the tubes 340a and 340b to form a flat sheet. In some implementations, the fibers 310 may be arranged to cross one another along a plane. For example, the fibers 310 may be arranged as a felt mat, such as Saint-Gobain Quartzel® low-density or high-density felts, or an aerogel where the fibers are pressed together to form a sheet. In another example, the shield assembly 300c may be formed by stacking multiple layers of fibers 310 where the fibers 310 in each layer are aligned parallel to one another, but oriented perpendicular to the fibers 310 in adjoining layers. In some implementations, the layers may be bonded together to form a laminated film. For example, the layers may be sintered together. In another example, the layers may be bonded using an adhesive (e.g., acrylic, polyimide, a ceramic-based adhesive).

The adhesive 352 may be disposed on one side of the film 350 to facilitate attachment of the shield assembly 300c to a portion of the vacuum chamber 110 or a component disposed in the cavity 111. In this manner, the ceramic fibers 310 may protect the adhesive 352 from the charged particles ejected by the plasma 40a. In some implementations, the ceramic fibers 310 forming the film may be wound or intertwined to maintain the shape of the film. In some implementations, the adhesive 352 may hold the ceramic fibers 310 in place, thus serving the dual purpose of attaching the shield assembly 300c to a portion of a component disposed in the vacuum chamber 110 or the vacuum chamber 110 itself and maintaining the desired arrangement of fibers 310.

For example, FIG. 8C shows a cutaway view of an interior portion of the chamber walls 120-1 and 120-2 where a shield assembly 300c-1 is placed over a portion of the gap 160b to keep the shield assembly 300a disposed in the gap 160b. FIG. 8C also shows the chamber wall 120-2 may include a port 122 through which a sensor 170 may be inserted into the cavity 111. As shown, another shield assembly 300c-2 may be applied to the interior surface of the chamber wall 120-2 to securely couple the sensor 170 to the chamber wall 120-2 and thus protect the sensor 170 from the plasma 40a.

The film 350 may have a thickness, t_{f}, that ranges between about 0.1 mm and about 50 mm, including all values and sub-ranges in between. It should be appreciated that the foregoing dimensional ranges is a non-limiting example. Similar to the shield assemblies 300a and 300b, the shield assembly 300c may readily bend and conform in shape to surfaces of varying geometries due to the mechanical compliance of the ceramic fibers 310. FIGS. 8A and 8B further show the adhesive 352 may not extend to the boundaries of the film 350, but instead may terminate at an offset distance, w_{f}, from the boundaries to reduce the likelihood of a charged particle 44 striking the adhesive 352 from the side of the shield assembly 300c. Although FIGS. 8A and 8B show the shield assembly 300c as having a rectangular film 350, it should be appreciated the film 350 may have other various geometries including, but not limited to, a square, a rectangle, a circle, an ellipse, or any combination of the foregoing. It should also be appreciated that the shield assembly 300c may not include the adhesive 352. Instead, the shield assembly 300c may be a mechanically compliant sheet that is cut into a desired shape and subsequently wrapped around a component or a portion of the vacuum chamber 110.

As described above, the ceramic fibers 310 in the shield assemblies 300a, 300b, and 300c may be arranged in a substantially parallel alignment or cross one another along a two-dimensional plane. However, it should be appreciated that the shield assemblies described herein may have other morphologies that form a tortuous trajectory to limit the transport of charged particles 44 and/or contaminants 46. For example, the fibers 310 may be arranged and distributed over a volume in an amorphous manner similar to cotton, such as in Saint-Gobain Quartzel® wool. The formation of shield assemblies using ceramic fibers is also non-limiting. In some implementations, the shield assemblies may be formed from fibers, particles, perforated films, or any combinations of the foregoing. For example, multiple perforated films may be layered onto one another to form a mat.

### An Example Method of Preparing and Installing a Ceramic Fiber Shield Assembly

In some implementations, the ceramic fibers 310 used to form the shield assemblies described herein may be a commercial off-the-shelf product, such as Saint-Gobain Quartzel® fiber. Typical commercial ceramic fibers are generally not suitable for use in a vacuum environment due, in part, to the presence of a plastic coating or a grease to facilitate manufacture of the fibers. Before the shield assembly is installed in the vacuum chamber 110, the ceramic fibers 310 may be cleaned to remove any undesirable (e.g., organic) materials on the ceramic fibers 310. For example, the ceramic fibers 310 may be placed into an oven (e.g., a kiln) and heated to a sufficiently high temperature to burn off organic materials without melting the ceramic fibers 310. In implementations where the ceramic fibers 310 are formed from SiO₂, the ceramic fibers 310 may be heated to a temperature of about 1200° C. for 24 hours and subsequently cooled to room temperature. It should be appreciated that the foregoing temperature and duration constitutes a non-limiting example. Other temperatures and/or durations may be used so long as organic materials are sufficiently removed without melting or altering the structure of the ceramic fibers. The ceramic fibers 310 may be cooled by turning off the oven and waiting until the ceramic fibers 310 reach room temperature.

In some implementations, the ceramic fibers 310 may be cut and formed into a desired shape before being cleaned. For example, the ceramic fibers 310 may be acquired already wound into a rope or a tube. In another example, the shield assembly may be arranged with its ends extending past each other for placement into the vacuum chamber 110 after cleaning. In some implementations, the ceramic fibers 310 may be cut and formed into a desired shape after being cleaned.

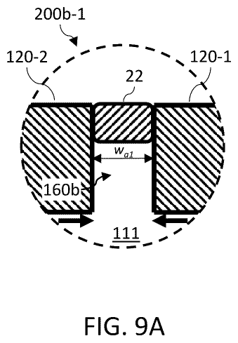

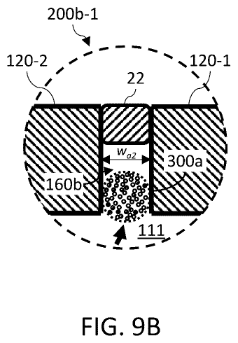

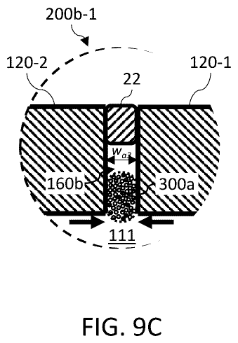

Once the ceramic fibers 310 forming the shield assembly are cleaned and formed into the desired shape, the shield assembly may be installed into the vacuum chamber 110. In some implementations, the shield assemblies in the gasket assemblies may be installed in separate steps from the gaskets as shown in FIGS. 9A-9C for the gasket assembly 200b-1. As shown in FIG. 9A, the gasket 22 may first be installed in the gap 160b between the chamber walls 120-1 and 120-2. The gap 160b may initially have a width, wₐ₁. FIG. 9B shows the chamber walls 120-1 and 120-2 may be pushed together, which may be accomplished by tightening a series of over bolts (not shown) disposed at opposing ends of the vacuum chamber 110. As shown, the chamber walls 120-1 and 120-2 may be pushed together to compress the portion of the gasket 22 until the gap 160b has a width, wₐ₂. This first compression step may narrow the gap 160b so that when the shield assembly 300a is placed in the gap 160b, the shield assembly 300a physically contacts the chamber walls 120-1 and 120-2, thus reducing the likelihood of the shield assembly 300a falling out form the gap 160b. Once the shield assembly 300a is installed, FIG. 9C shows the chamber walls 120-1 and 120-2 are compressed until the gap 160b has a width, was, at which point the gasket 22 seals the gap 160b from the ambient environment and the shield assembly 300a is compressed to form the desired tortuous trajectory reducing transport of charged particle 44 and/or contaminants 46.

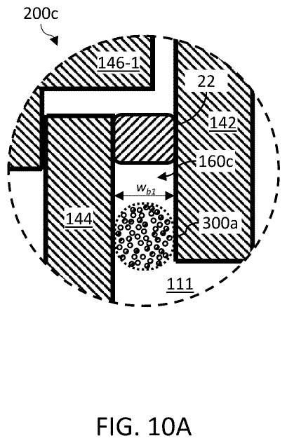

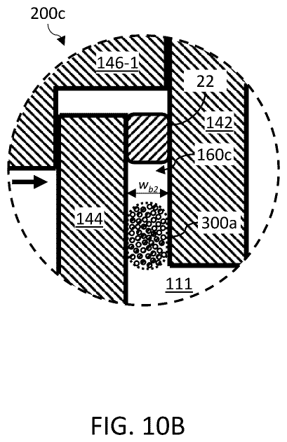

In some implementations, the shield assemblies and the gaskets may be installed at the same time and compressed together. For example, FIGS. 10A and 10B show the installation of the gasket assembly 200c in the chamber endplate 140b. As shown in FIG. 10A, the gasket 22 and the shield assembly 300a may be initially placed in the gap 160c together. This may be achieved, in part, by the gap having a width, w_{b1}, sufficiently small to retain both the gasket 22 and the shield assembly 300a. Once the gasket 22 and the shield assembly 300a are installed, the window 144 may be pressed onto the baseplate 142 via one or more clamps 146 until the gap 160c has a width, w_{b2}. At this point, the gasket 22 may be sufficiently compressed to seal the gap 160c and the shield assembly 300a may be compressed to form the desired tortuous trajectories described above.

The shield assemblies used to protect the other components in the vacuum chamber 110 (e.g., wires, sensors), may be installed through appropriate feedthrough ports on the vacuum chamber 110. The shield assemblies may be further supported by the feedthroughs or attached to the interior surfaces of the vacuum chamber 110 via, for example, the shield assembly 300c, which again may be used as a tape. For example, the component 330 may be inserted into the cavity 342 of the tube 340a prior to installation into the vacuum chamber 110.

As described above, the chamber walls 120, the chamber endplates 140a and 140b, and the various shield assemblies deployed in the vacuum chamber 110 may be formed from the same ceramic material. Thus, the plasma 40a may eject charged particles 44 that primarily interact with the same ceramic material and, hence, produce the same contaminants that are less reactive or, in some instances, not reactive with the plasma 40a.

Additionally, the presence of the shield assemblies in the gaps of the vacuum chamber 110 may also allow the interior surfaces of the vacuum chamber 110 to be cleaned with a plasma without generating additional contaminants. Generally, the interior surfaces of vacuum chambers are prone to surface contamination whenever the cavity is exposed to the ambient environment. For example, contaminants in the ambient environment, such as water molecules, may be adsorbed onto the interior surfaces of the vacuum chamber during assembly and/or maintenance of the vacuum chamber system. In particular, water molecules may infiltrate the cavity 111 of the vacuum chamber 110 when the vacuum chamber is open and exposed to the ambient environment. During operation, the plasma may also eject charged particles and/or reaction products, which may be adsorbed as contaminants. When the vacuum chamber is subsequently pumped down to vacuum, the adsorbed contaminants may take longer to remove due to the surface adhesion forces binding the contaminants to the surfaces of the vacuum chamber, thus increasing the time to reach a desired vacuum level.

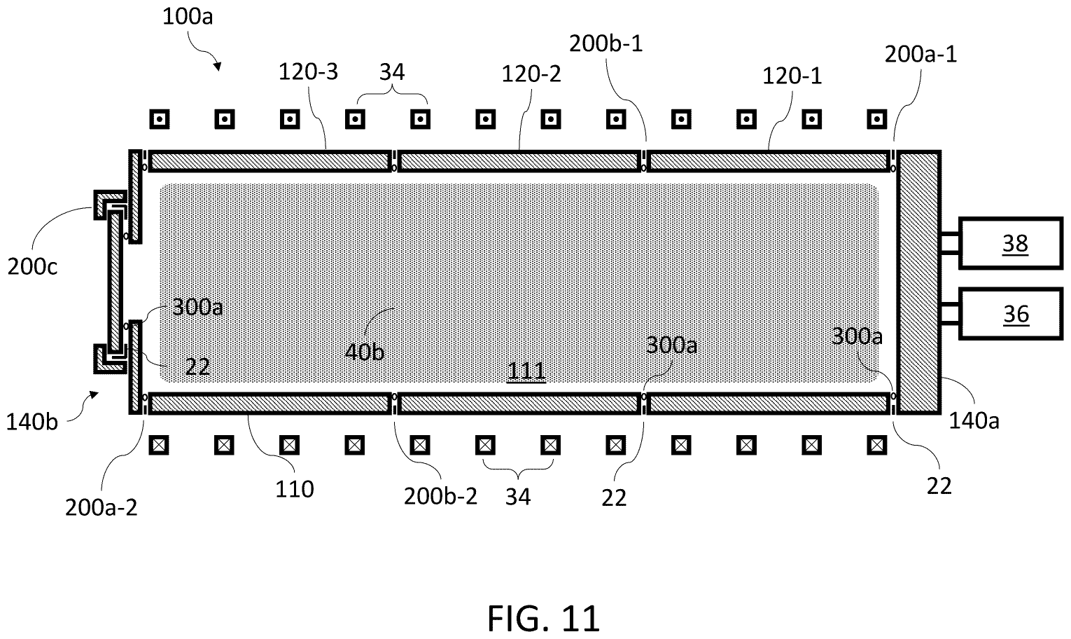

The rate of removal of the adsorbed contaminants may be increased by heating the interior surfaces of the vacuum chamber using, for example, a plasma. However, the exposure of the gaskets, especially elastomeric gaskets, may generate additional contaminants within the vacuum chamber. The presence of the shield assemblies, however, may suppress the generation of additional contaminants, thus permitting the use of a plasma to accelerate the removal of the adsorbed contaminants. For example, FIG. 11 shows another view of the vacuum chamber system 100a where the cavity 111 is substantially filled with a plasma 40b to locally heat the interior surfaces of the vacuum chamber 110. A vacuum chamber is substantially filled with this plasma when most or all of the portions of the vacuum chamber 110 that are likely to be contaminated during operation are reached by the plasma 40b. When the temperature of the interior surfaces increases, the rate at which the adsorbed contaminants are removed from the surfaces and purged by the pump increases.

Compared to the plasma 40a, the plasma 40b may be at a lower energy and, thus, less likely to sputter off additional contaminants from the ceramic materials used to form the shield assemblies, the chamber walls, and/or the chamber endplates. For example, the plasma 40b may have an energy of about 1 eV. However, it should be appreciated the plasma 40a may also be used to facilitate cleaning and removal of adsorbed contaminants. More generally, the plasma used to clean the vacuum chamber 110 may have an energy that ranges between about 1 eV and about 100 eV, including all values and sub-ranges in between. It should be appreciated that the foregoing range of energies for the plasma is a non-limiting example. In some implementations, the plasma 40b may be present for a brief period of time sufficient to raise the temperature of the interior surfaces of the vacuum chamber 110. In one example, the exposure of the interior surfaces to the plasma 40b may be modulated by modulating the magnetic field generated by the magnetic field source 34 so that the heat transferred to the interior surfaces of the vacuum chamber 110 may dissipate to the ambient environment. In some implementations, the vacuum chamber system 100a may periodically use the plasma 40b to clean the interior surfaces of the vacuum chamber 110 after initial pump down to vacuum and/or between cycles where the plasma 40a is used. In this manner, the vacuum chamber 110 may be periodically cleaned without breaking vacuum.

An Example Plasma Propulsion System with Ceramic Fiber Shield Assemblies

The shield assemblies described above are not limited to vacuum chamber systems. In some implementations, the shield assemblies may be incorporated into systems that operate in a naturally occurring vacuum environment, such as space. For example, the shield assemblies may be deployed in a plasma propulsion system on a spacecraft to separate one or more internal compartments of the spacecraft from the surrounding vacuum environment.

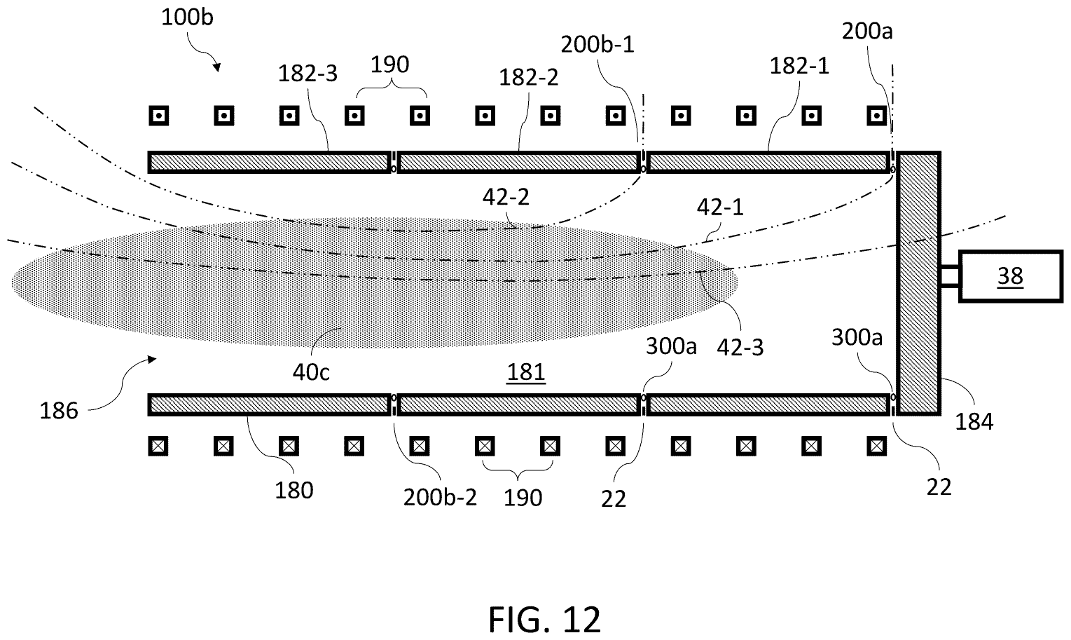

FIG. 12 shows an example plasma propulsion system 100b. As shown, the plasma propulsion system 100b includes a plasma propulsion chamber 180 assembled from chamber walls 182-1, 182-2, and 182-3 (also referred to herein as a “chamber wall 182”) and a chamber endplate 184 that together define a cavity 181. The plasma propulsion system 100b further includes a plasma source 38 to provide the plasma 40c used for propulsion. Additionally, the plasma propulsion system 100b may include magnetic field source 190 that generates a magnetic field, a portion of which is represented by the magnetic field lines 44-1, 44-2, and 44-3, to propel the plasma out through an exhaust 186 for propulsion.

Additional examples of plasma propulsion systems may be found in U.S. application Ser. No. 14/750,771, now issued as U.S. Pat. No. 9,524,802, filed on Jun. 25, 2015, entitled, “Apparatus and methods for fusion based power generation and engine thrust generation,” which is incorporated by reference herein in its entirety.

The chamber walls 182 and chamber endplate 184 may have the same geometry and dimensions as the chamber walls 120 and chamber endplates 140a and 140b. The chamber walls 182 and chamber endplate 184 may also be formed from the same materials as the chamber walls 120 and chamber endplates 140a and 140b.

FIG. 12 further shows the plasma propulsion chamber 180 may include the gasket assembly 200a between the chamber wall 182-1 and the chamber endplate 184 and gasket assemblies 200b-1 and 200b-2 disposed between the chamber walls 182-1 and 182-2 and the chamber walls 182-12 and 182-3, respectively. As described above, the gasket assemblies 200a, 200b-1, and 200b-2 may include a shield assembly (e.g., the shield assembly 300a) to protect the gaskets 22 from the plasma 40c. In some implementations, the plasma propulsion system 100b may include a sensor, wire, or other device disposed in the cavity 181 or near the exhaust 186. The shield assemblies 200b or 200c may be used to protect the foregoing components from the plasma 40c.

### CONCLUSION

All parameters, dimensions, materials, and configurations described herein are meant to be exemplary and the actual parameters, dimensions, materials, and/or configurations will depend upon the specific application or applications for which the inventive teachings is/are used. It is to be understood that the foregoing embodiments are presented primarily by way of example and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein.

In addition, any combination of two or more such features, systems, articles, materials, kits, and/or methods, if such features, systems, articles, materials, kits, and/or methods are not mutually inconsistent, is included within the inventive scope of the present disclosure. Other substitutions, modifications, changes, and omissions may be made in the design, operating conditions and arrangement of respective elements of the exemplary implementations without departing from the scope of the present disclosure. The use of a numerical range does not preclude equivalents that fall outside the range that fulfill the same function, in the same way, to produce the same result.

Also, various inventive concepts may be embodied as one or more methods, of which at least one example has been provided. The acts performed as part of the method may in some instances be ordered in different ways. Accordingly, in some inventive implementations, respective acts of a given method may be performed in an order different than specifically illustrated, which may include performing some acts simultaneously (even if such acts are shown as sequential acts in illustrative embodiments).

All publications, patent applications, patents, and other references mentioned herein are incorporated by reference in their entirety.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A vacuum chamber system, comprising:
a vacuum chamber defining a cavity configured to contain a plasma, the vacuum chamber including:
a set of chamber components, the set of chamber components defining a cavity and one or more gaps where each gap of the one or more gaps is defined between two or more chamber components of the set of chamber components;
one or more gaskets, each gasket of the one or more gaskets being disposed in a corresponding gap of the one or more gaps to provide a seal for that gap; and
one or more shield assemblies, each shield assembly of the one or more shield assemblies comprising a plurality of ceramic fibers disposed between a corresponding gasket of the one or more gaskets and the cavity, the plurality of ceramic fibers reducing exposure of that gasket to charged particles ejected by the plasma during operation of the vacuum chamber system;
a pump, coupled to the vacuum chamber, to evacuate the cavity of the vacuum chamber; and
a plasma source, coupled to the vacuum chamber, to generate the plasma.

2. The vacuum chamber system of claim 1, wherein the plurality of ceramic fibers of at least one shield assembly of the one or more shield assemblies forms a rope.

3. The vacuum chamber system of claim 1, wherein the plurality of ceramic fibers of at least one shield assembly of the one or more shield assemblies forms a tube.

4. The vacuum chamber system of claim 1, wherein the plurality of ceramic fibers of at least one shield assembly of the one or more shield assemblies forms a sheet.

5. The vacuum chamber system of claim 1, wherein the plurality of ceramic fibers of at least one shield assembly of the one or more shield assemblies forms a packed structure where each ceramic fiber of that plurality of ceramic fibers is:
either in physical contact with another ceramic fiber of that plurality of ceramic fibers or separate from another ceramic fiber of that plurality of ceramic fibers by an interstitial space; and
disposed within an envelope.

6. The vacuum chamber system of claim 5, wherein the interstitial space ranges from about 0 μm to about 100 μm.

7. The vacuum chamber system as in any of claims 2-6, wherein the plurality of ceramic fibers of the at least one shield assembly is disposed in the corresponding gap with the corresponding gasket of the one or more gaskets.

8. The vacuum chamber system as in any of claims 2-6, wherein the at least one shield assembly further comprises:
an adhesive, coupled to the plurality of ceramic fibers, to securely couple the at least one shield assembly to the vacuum chamber.

9. The vacuum chamber system as in any of claims 2-6, wherein:
the plurality of ceramic fibers of the at least one shield assembly has a first end and a second end and is arranged such that the first and second ends extend past each other to form a closed loop.

10. The vacuum chamber system of claim 1, wherein each ceramic fiber of the plurality of ceramic fibers of at least one shield assembly of the one or more shield assemblies has a diameter from about 0.1 μm to about 100 μm.

11. The vacuum chamber system of claim 1, wherein each ceramic fiber of the plurality of ceramic fibers of at least one shield assembly of the one or more shield assemblies has a length from about 0.1 m to about 100 m.

12. The vacuum chamber system of claim 1, wherein the plurality of ceramic fibers of at least one shield assembly of the one or more shield assemblies is composed of at least one of SiO₂, Al₂O₃, BN, BC, SiN, or AlN.

13. The vacuum chamber system of claim 1, wherein:
the plurality of ceramic fibers of at least one shield assembly of the one or more shield assemblies is composed of SiO₂; and
a mass fraction of the SiO₂ is greater than or equal to about 0.98.

14. The vacuum chamber system of claim 1, wherein:
the plurality of ceramic fibers of at least one shield assembly of the one or more shield assemblies is composed of SiO₂; and
a mass fraction of the SiO₂ is greater than or equal to about 0.9995.

15. The vacuum chamber system of claim 1, wherein:
the plurality of ceramic fibers of at least one shield assembly of the one or more shield assemblies is composed of SiO₂ and BN;
a mass fraction of the SiO₂ ranges from about 0.4 to about 0.6; and
a mass fraction of the BN ranges from about 0.4 to about 0.6.

16. The vacuum chamber system of claim 1, wherein:
the plurality of ceramic fibers of at least one shield assembly of the one or more shield assemblies is composed of a first ceramic; and
the set of chamber components is composed of a material that includes a second ceramic.

17. The vacuum chamber system of claim 16, wherein the first ceramic is the same as the second ceramic.

18. The vacuum chamber system of claim 17, wherein the first ceramic is SiO₂.

19. The vacuum chamber system of claim 1, wherein at least one gasket of the one or more gaskets is composed of an elastomer or a metal.

20. The vacuum chamber system of claim 19, wherein the at least one gasket is composed of the elastomer, the elastomer including at least one of Buna-N, silicone, fluorocarbon, or perfluorocarbon.

21. The vacuum chamber system of claim 19, wherein the at least one gasket is composed of the metal, the metal including at least one of copper or aluminum.

22. The vacuum chamber system of claim 1, wherein:
the set of chamber components includes a first chamber wall and a first chamber endplate coupled to the first chamber wall; and
one gap of the one or more gaps is formed between the first chamber wall and the first chamber endplate.

23. The vacuum chamber system of claim 1, wherein:
the set of chamber components includes a first chamber wall and a second chamber wall coupled to the first chamber wall; and
one gap of the one or more gaps is formed between the first and second chamber walls.

24. The vacuum chamber system of claim 1, wherein:
the set of chamber components includes a chamber endplate, the chamber endplate comprising:
a base plate defining an aperture;
a window covering the aperture; and
a clamp to couple the window to the base plate; and
one gap of the one or more gaps is formed between the window and the base plate.

25. The vacuum chamber system of claim 1, wherein:
the one or more shield assemblies is one or more first shield assemblies; and
the vacuum chamber system further comprises:
a second shield assembly comprising a plurality of ceramic fibers forming a tube; and
an elastically deformable rod disposed in the tube,
wherein the second shield assembly reduces exposure of the elastically deformable rod to charged particles ejected by the plasma during operation of the vacuum chamber system.

26. The vacuum chamber system of claim 25, wherein the rod is formed of fiberglass.

27. The vacuum chamber system of claim 1, wherein:
the one or more shield assemblies is one or more first shield assemblies; and
the vacuum chamber system further comprises:
a second shield assembly comprising a plurality of ceramic fibers forming a tube; and
a sensor disposed in the tube,
wherein the second shield assembly reduces exposure of the sensor to charged particles ejected by the plasma during operation of the vacuum chamber system.

28. The vacuum chamber system of claim 1, wherein:
the one or more shield assemblies is one or more first shield assemblies; and
the vacuum chamber system further comprises:
a sensor disposed in the cavity of the vacuum chamber;
a second shield assembly comprising a plurality of ceramic fibers forming a tube; and
an electrical wire, disposed in the tube, to provide at least one of electrical power or data communication to the sensor,
wherein the second shield assembly reduces exposure of the electrical wire to charged particles ejected by the plasma during operation of the vacuum chamber system.

29. The vacuum chamber system of claim 1, wherein:
the one or more shield assemblies is one or more first shield assemblies; and
the vacuum chamber system further comprises:
a second shield assembly comprising:
a plurality of ceramic fibers forming a sheet; and
an adhesive, disposed on one side of the sheet, to adhere the second shield assembly to an interior surface of the vacuum chamber; and
a sensor disposed between the second shield assembly and the interior surface of the vacuum chamber,
wherein the second shield assembly reduces exposure of the sensor to charged particles ejected by the plasma during operation of the vacuum chamber system.

30. The vacuum chamber system of claim 1, wherein:
the one or more shield assemblies is one or more first shield assemblies; and
the vacuum chamber system further comprises:
a sensor disposed in the cavity of the vacuum chamber;
a second shield assembly comprising:
a plurality of ceramic fibers forming a sheet; and
an adhesive, disposed on one side of the sheet, to adhere the second shield assembly to an interior surface of the vacuum chamber; and
an electrical wire, disposed between the second shield assembly and the interior surface of the vacuum chamber, to provide at least one of electrical power or data communication to the sensor,
wherein the second shield assembly reduces exposure of the electrical wire to charged particles ejected by the plasma during operation of the vacuum chamber system.

31. The vacuum chamber system as in any of claims 27-30, wherein the sensor comprises at least one of a magnetic field sensor, a magnetic flux sensor, a plasma density sensor, a temperature sensor, a Langmuir probe, a sensor to detect neutrons in the cavity, a sensor to detect alpha particles in the cavity, or a sensor to detect electrons in the cavity.

32. The vacuum chamber system of claim 1, wherein the cavity of the vacuum chamber is configured to be evacuated to a pressure less than or equal to about 10⁻³ Torr.

33. The vacuum chamber system of claim 1, further comprising:
a magnetic field source, coupled to the vacuum chamber, having one or more magnetic coils to generate a magnetic field in the cavity of the vacuum chamber to modify a shape of the plasma during operation of the vacuum chamber system.

34. A method of assembling a vacuum chamber system, the vacuum chamber system comprising:
a vacuum chamber defining a cavity, the vacuum chamber comprising:
a set of chamber components, the set of chamber components defining a cavity and one or more gaps where each gap of the one or more gaps is defined between two or more chamber components of the set of chamber components;
one or more gaskets, each gasket of the one or more gaskets being configured for placement in a corresponding gap of the one or more gaps to provide a seal for that gap; and
one or more shield assemblies, each shield assembly of the one or more shield assemblies comprising a plurality of ceramic fibers configured for placement between a corresponding gasket of the one or more gaskets and the cavity;
the method comprising, for each shield assembly of the one or more shield assemblies:
removing organic materials disposed on the plurality of ceramic fibers;
placing the corresponding gasket into the corresponding gap defined by the set of chamber components;
placing the shield assembly between the corresponding gasket and the cavity of the vacuum chamber; and
clamping together the set of chamber components to compress the corresponding gasket and seal the corresponding gap.

35. The method of claim 34, further comprising:
coupling a pump to the vacuum chamber, the pump being configured to evacuate the cavity of the vacuum chamber.

36. The method of claim 35, further comprising:
coupling a plasma source to the vacuum chamber, the plasma source being configured to generate a plasma contained in the cavity of the vacuum chamber.

37. The method of claim 36, further comprising:
evacuating, by the pump, the cavity of the vacuum chamber; and
generating, by the plasma source, a plasma in the cavity of the vacuum chamber,
wherein, while the plasma is present in the cavity, each shield assembly of the one or more shield assemblies reduces exposure of the corresponding gasket to charged particles ejected by the plasma.

38. The method of claim 34, further comprising, while removing the organic materials:
removing unbound contaminants disposed on the plurality of ceramic fibers.

39. The method of claim 34, further comprising, before removing the organic materials disposed on the plurality of ceramic fibers:
shaping the plurality of ceramic fibers into one of a rope, a tube, or a sheet.

40. The method of claim 34, wherein removing the organic materials from the plurality of ceramic fibers comprises:
heating the plurality of ceramic fibers to a temperature of about 1200° C. for about 24 hours; and
cooling the plurality of ceramic fibers to room temperature.

41. The method of claim 34, wherein:
placing the shield assembly between the corresponding gasket and the cavity of the vacuum chamber comprises:
inserting the shield assembly into the corresponding gap; and
clamping together the set of chamber components to push the plurality of ceramic fibers together and increasing the density of the plurality of ceramic fibers.

42. The method of claim 34, wherein:
the shield assembly further comprises an adhesive disposed on one side of the plurality of ceramic fibers; and
placing the shield assembly between the corresponding gasket and the cavity of the vacuum chamber comprises:
attaching the plurality of ceramic fibers to at least one interior surface of the vacuum chamber via the adhesive such that the plurality of ceramic fibers covers the corresponding gap.

43. A vacuum chamber, comprising:
a set of chamber components, the set of chamber components defining a cavity, a first chamber component and a second chamber component of the set of chamber components defining a gap therebetween;
a gasket, disposed in the gap, to seal the gap defined by the first chamber component and the second chamber component; and
a shield assembly, disposed between the gasket and the cavity, including a plurality of ceramic fibers,
wherein the cavity is configured to be evacuated.

44. The vacuum chamber of claim 43, wherein the vacuum chamber is couplable to a pump to evacuate the cavity of the vacuum chamber.

45. The vacuum chamber of claim 43, wherein the cavity is configured to be evacuated to a pressure less than or equal to about 10⁻³ Torr.

46. A vacuum chamber system, comprising:
the vacuum chamber of claim 43;
a pump; and
a plasma source, coupled to the vacuum chamber, to generate a plasma in the cavity of the vacuum chamber,
wherein, during operation of the vacuum chamber system, the plurality of ceramic fibers of the shield assembly reduces exposure of the gasket to charged particles ejected by the plasma.

47. The vacuum chamber system of claim 46, further comprising:
a magnetic field source, coupled to the vacuum chamber, to generate a magnetic field in the cavity of the vacuum chamber to modify at least one of a shape or size of the plasma during use.

48. The vacuum chamber of claim 43, wherein the plurality of ceramic fibers forms a rope.

49. The vacuum chamber of claim 43, wherein the plurality of ceramic fibers forms a tube.

50. The vacuum chamber of claim 43, wherein the plurality of ceramic fibers forms a sheet.

51. The vacuum chamber of claim 43, wherein the plurality of ceramic fibers forms a packed structure where each ceramic fiber of that plurality of ceramic fibers is:
either in physical contact with another ceramic fiber of the plurality of ceramic fibers or separate from another ceramic fiber of the plurality of ceramic fibers by an interstitial space; and
disposed within an envelope.

52. The vacuum chamber of claim 51, wherein the interstitial space ranges from about 0 μm to about 100 μm.

53. The vacuum chamber as in any of claims 48-52, wherein the shield assembly further comprises:
an adhesive, coupled to the plurality of ceramic fibers, to securely couple the shield assembly to the vacuum chamber.

54. The vacuum chamber as in any of claims 48-52, wherein:
the plurality of ceramic fibers has a first end and a second end and is arranged such that the first and second ends extend past each other to form a closed loop.

55. The vacuum chamber of claim 43, wherein each ceramic fiber of the plurality of ceramic fibers has a diameter from about 0.1 μm to about 100 μm.

56. The vacuum chamber of claim 43, wherein each ceramic fiber of the plurality of ceramic fibers has a length from about 0.1 m to about 100 m.

57. The vacuum chamber of claim 43, wherein the plurality of ceramic fibers is composed of at least one of SiO₂, Al₂O₃, BN, BC, SiN, or AlN.

58. The vacuum chamber of claim 43, wherein:
the plurality of ceramic fibers is composed of SiO₂; and
a mass fraction of the SiO₂ is greater than or equal to about 0.98.

59. The vacuum chamber of claim 43, wherein:
the plurality of ceramic fibers is composed of SiO₂; and
a mass fraction of the SiO₂ is greater than or equal to about 0.9995.

60. The vacuum chamber of claim 43, wherein:
the plurality of ceramic fibers is composed of SiO₂ and BN;
a mass fraction of the SiO₂ ranges from about 0.4 to about 0.6; and
a mass fraction of the BN ranges from about 0.4 to about 0.6.

61. The vacuum chamber of claim 43, wherein:
the plurality of ceramic fibers is composed of a first ceramic; and
the set of chamber components is composed of a material that includes a second ceramic.

62. The vacuum chamber of claim 61, wherein the first ceramic is the same as the second ceramic.

63. The vacuum chamber of claim 62, wherein the first ceramic is SiO₂.

64. The vacuum chamber of claim 43, wherein the gasket is composed of an elastomer or a metal.

65. The vacuum chamber of claim 64, wherein the gasket is composed of the elastomer, the elastomer including at least one of Buna-N, silicone, fluorocarbon, or perfluorocarbon.

66. The vacuum chamber of claim 64, wherein the gasket is composed of the metal, the metal including at least one of copper or aluminum.

67. The vacuum chamber of claim 43, wherein:
the shield assembly is a first shield assembly and the plurality of ceramic fibers is a first plurality of ceramic fibers; and
the vacuum chamber further comprises:
a second shield assembly comprising a second plurality of ceramic fibers forming a tube; and
an elastically deformable rod disposed in the tube.

68. The vacuum chamber of claim 67, wherein the rod is formed of fiberglass.

69. The vacuum chamber of claim 43, wherein:
the shield assembly is a first shield assembly and the plurality of ceramic fibers is a first plurality of ceramic fibers; and
the vacuum chamber system further comprises:
a second shield assembly comprising a second plurality of ceramic fibers forming a tube; and
a sensor disposed in the tube.

70. The vacuum chamber of claim 43, wherein:
the shield assembly is a first shield assembly and the plurality of ceramic fibers is a first plurality of ceramic fibers; and
the vacuum chamber system further comprises:
a sensor disposed in the cavity of the vacuum chamber;
a second shield assembly comprising a second plurality of ceramic fibers forming a tube; and
an electrical wire, disposed in the tube, to provide at least one of electrical power or data communication to the sensor.

71. The vacuum chamber of claim 43, wherein:
the shield assembly is a first shield assembly and the plurality of ceramic fibers is a first plurality of ceramic fibers; and
the vacuum chamber system further comprises:
a second shield assembly comprising:
a second plurality of ceramic fibers forming a sheet; and
an adhesive, disposed on one side of the sheet, to adhere the second shield assembly to an interior surface of the vacuum chamber; and
a sensor disposed between the second shield assembly and the interior surface of the vacuum chamber.

72. The vacuum chamber of claim 43, wherein:
the shield assembly is a first shield assembly and the plurality of ceramic fibers is a first plurality of ceramic fibers; and
the vacuum chamber system further comprises:
a sensor disposed in the cavity of the vacuum chamber;
a second shield assembly comprising:
a second plurality of ceramic fibers forming a sheet; and
an adhesive, disposed on one side of the sheet, to adhere the second shield assembly to an interior surface of the vacuum chamber; and
an electrical wire, disposed between the second shield assembly and the interior surface of the vacuum chamber, to provide at least one of electrical power or data communication to the sensor.

73. The vacuum chamber as in any of claims 69-72, wherein the sensor comprises at least one of a magnetic field sensor, a magnetic flux sensor, a plasma density sensor, a temperature sensor, a Langmuir probe, a sensor to detect neutrons in the cavity, a sensor to detect alpha particles in the cavity, or a sensor to detect electrons in the cavity.

74. The vacuum chamber of claim 43, wherein the cavity of the vacuum chamber is configured to be evacuated to a pressure less than or equal to about 10⁻³ Torr.

75. A vacuum chamber, comprising:
a set of chamber components defining a cavity; and
a shield assembly, disposed in the cavity, including a plurality of ceramic fibers,
wherein the cavity is configured to be evacuated.

76. The vacuum chamber of claim 75, wherein the vacuum chamber is couplable to a pump to evacuate the cavity of the vacuum chamber.

77. The vacuum chamber of claim 75, wherein the cavity is configured to be evacuated to a pressure less than or equal to about 10⁻³ Torr.

78. A vacuum chamber system, comprising:
the vacuum chamber of claim 75;
a pump; and
a plasma source, coupled to the vacuum chamber, to generate a plasma in the cavity of the vacuum chamber,
wherein, during operation of the vacuum chamber system, the plurality of ceramic fibers of the shield assembly reduces transport of charged particles ejected by the plasma across the shield assembly.

79. The vacuum chamber of claim 75, wherein:
the plurality of ceramic fibers forms a tube; and
the vacuum chamber further comprises:
an elastically deformable rod disposed in the tube.

80. The vacuum chamber of claim 79, wherein the rod is formed of fiberglass.

81. The vacuum chamber of claim 75, wherein:
the plurality of ceramic fibers forms a tube; and
the vacuum chamber further comprises:
a sensor disposed in the tube.

82. The vacuum chamber of claim 75, wherein:
the plurality of ceramic fibers forms a tube; and
the vacuum chamber further comprises:
a sensor disposed in the cavity; and
an electrical wire, disposed in the tube, to provide at least one of electrical power or data communication to the sensor.

83. The vacuum chamber of claim 75, wherein:
the plurality of ceramic fibers forms a sheet;
the shield assembly further comprises:
an adhesive, disposed on one side of the sheet, to adhere the second shield assembly to an interior surface of the vacuum chamber; and
the vacuum chamber further comprises:
a sensor disposed between the shield assembly and the interior surface of the vacuum chamber.

84. The vacuum chamber of claim 75, wherein:
the plurality of ceramic fibers forms a sheet;
the shield assembly further comprises:
an adhesive, disposed on one side of the sheet, to adhere the second shield assembly to an interior surface of the vacuum chamber; and
the vacuum chamber further comprises:
a sensor disposed in the cavity; and
an electrical wire, disposed between the shield assembly and the interior surface of the vacuum chamber, to provide at least one of electrical power or data communication to the sensor.

85. The vacuum chamber as in any of claims 81-84, wherein the sensor comprises at least one of a magnetic field sensor, a magnetic flux sensor, a plasma density sensor, a temperature sensor, a Langmuir probe, a sensor to detect neutrons in the cavity, a sensor to detect alpha particles in the cavity, or a sensor to detect electrons in the cavity.

86. A method of cleaning a vacuum chamber system, the vacuum chamber system comprising:
a vacuum chamber defining a cavity, the vacuum chamber comprising;
a gasket formed of an elastomer; and
a shield assembly having a plurality of ceramic fibers;
a plasma source coupled to the vacuum chamber; and
a pump coupled the vacuum chamber,
the method comprising:
injecting a plasma into the cavity of the vacuum chamber such that the plasma fills the cavity thereby locally heating interior surfaces of the vacuum chamber;
while the interior surfaces of the vacuum chamber are heated, removing first contaminants released from the interior surfaces of the vacuum chamber using the pump,
wherein the shield assembly suppresses generation of second contaminants from the gasket by reducing transport of charged particles from the plasma to the gasket.
